(19) United States
(12) Patent Application Publication
(10) Pub. No.: US 2011/0074749 A1
(43) Pub. Date: Mar. 31, 2011

(54) THIN FILM TRANSISTOR ARRAY SUBSTRATE, LIGHT-EMITTING PANEL AND MANUFACTURING METHOD THEREOF AS WELL AS ELECTRONIC DEVICE

(75) Inventor: Toshiaki HIGASHI, Yokohama-shi (JP)

(73) Assignee: CASIO COMPUTER CO., LTD., Tokyo (JP)

(21) Appl. No.: 12/891,839

(22) Filed: Sep. 28, 2010

(30) Foreign Application Priority Data
Sep. 30, 2009 (JP) 2009-226156

(51) Int. Cl. G09G 5/00; H01L 33/08

(52) U.S. Cl. 345/206; 438/34; 257/E33.053

(57) ABSTRACT

A thin film transistor array substrate includes a substrate, thin film transistors formed on the substrate, wirings provided on the substrate. The wirings are subjected to an application of a voltage to drive circuits including the thin film transistors. At least part of the surface of each of the wirings is made of an anodic oxide film.

### CROSS-REFERENCE TO RELATED APPLICATIONS

This application is based upon and claims the benefit of priority from prior Japanese Patent Application No. 2009-226156, filed Sep. 30, 2009, the entire contents of which are incorporated herein by reference.

### BACKGROUND OF THE INVENTION

1. Field of the Invention

The present invention relates to a thin film transistor array substrate.

2. Description of the Related Art

Recently, as a display apparatus for an electronic device such as a mobile telephone or portable music player, there has been known a display apparatus that uses a display panel (light-emitting element type display panel) in which light-emitting elements such as organic electroluminescent elements (hereinafter abbreviated as “organic EL elements”) are two-dimensionally arranged. As compared with a widespread liquid crystal display apparatus, the light-emitting element type display panel to which an active matrix driving method is applied, in particular, has the advantages of a higher display response speed and lower viewing angle dependence, and is capable of higher luminance, higher contrast and higher display image quality. Moreover, the light-emitting element type display panel needs no backlight and no light guide plate in contrast with the liquid crystal display apparatus, and therefore has an advantage of being capable of further reductions in thickness and weight.

When such a display panel is enhanced in the image quality or increased in the size of its screen, there is a significant signal delay or voltage drop because the length of wirings from a driver varies depending on the location of pixels having light-emitting elements. To solve such a problem, it is necessary to apply a low-resistance wiring structure to the above-mentioned display panel. For example, Jpn. Pat. Appln. KOKAI Publication No. 2009-116206 describes the use of simple aluminum or an aluminum alloy as a wiring material for a power supply wire to reduce wiring resistance in an organic EL panel in which pixels having organic EL elements are arranged.

Here, as is well known, the organic EL element has an element structure in which an anode (positive electrode) electrode, an organic EL layer (light-emitting function layer) and a cathode (negative electrode) electrode are stacked in order on one side of, for example, a glass substrate. If a voltage is applied to the organic EL layer across the anode electrode and the cathode electrode to surpass a light emission threshold, light (excitation light) is radiated in accordance with energy generated when injected holes and electrons recombine in the organic EL layer. (See Jpn. Pat. Appln. KOKAI Publication No. 2009-116206).

In the above-mentioned display panel to which the active matrix driving method is applied, each pixel needs to have not only the light-emitting element but also a circuit element such as a thin film transistor (TFT) serving as a switching element. Such a circuit element is configured by stacking and forming a conducting layer and an insulating film on a substrate after one or more film formation and patterning steps. In this case, the substrate is required to be highly clean.

However, a greater number of film formation and patterning steps facilitate the generation of particles (small foreign objects) on the substrate. Thus, the anode electrode and the cathode electrode cause a short circuit due to the remaining particles, leading to the generation of point defects and decreased manufacturing yield (increased defective rate). That is, when a liquid crystal element structure is compared with an organic EL element structure, the light-emitting function layer in the organic EL element is much thinner than a liquid crystal layer in a liquid crystal element and is therefore higher in the probability of the point defect generation attributed to the particles. Moreover, when the display panel is enhanced in the image quality or increased in the size of its screen as described above, the influence of the particles is relatively great.

### BRIEF SUMMARY OF THE INVENTION

According to an aspect of an embodiment, a thin film transistor array substrate includes a substrate, thin film transistors formed on the substrate, wirings provided on the substrate. The wirings are subjected to an application of a voltage to drive circuits including the thin film transistors. At least part of the surface of each of the wirings comprises an anodic oxide film.

According to another aspect of an embodiment, a light-emitting panel includes a substrate, light-emitting elements formed on the substrate, thin film transistors configured to drive the light-emitting elements, and wirings to which a voltage to drive the light-emitting elements is applied by the thin film transistors. At least part of the surface of each of the wirings comprises an anodic oxide film.

According to still another aspect of an embodiment, a method of manufacturing a light-emitting panel, which includes a substrate provided with pixels including at least light-emitting elements and thin film transistors to drive the light-emitting elements, includes forming wirings to which a voltage to drive the light-emitting elements is applied, and forming at least part of the surface of each of the wirings by an anodic oxidation treatment.

Advantages of the invention will be set forth in the description which follows, and in part will be obvious from the description, or may be learned by practice of the invention. The advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

The present invention will be fully understood by the following detailed description and the accompanying drawings, which are only illustrative and do not limit the scope of the invention, wherein:

FIGS. 1A and 1B are schematic plan views showing an example of a display panel to which a thin film transistor array substrate according to an embodiment is applied;

FIG. 2 is a schematic plan view showing one example of how pixels are arranged and how a wiring layer is provided in the display panel according to the embodiment;

FIG. 3 is an equivalent circuit diagram showing an example of the circuit configuration of each of the pixels arranged in the display panel according to the embodiment;

FIG. 4 is a plan layout view showing an example of a pixel applicable to the embodiment;

FIGS. 5A and 5B are enlarged views of essential parts of the pixel according to the embodiment;

FIGS. 6A, 6B, 7A, 7B, 7C, 7D, 8A, 8B, 9A, and 9B are sectional views of essential parts of the display panel according to the embodiment;

FIGS. 10A, 10B, 10C, 11A, 11B, 11C, 12A, 12B, 12C, 13A, 13B, 14A, and 14B are process sectional views showing a display panel manufacturing method according to the embodiment;

FIGS. 15A and 15B are sectional views of essential parts showing one example of a comparative display panel;

FIGS. 16A, 16B, 16C, 17A, and 17B are process sectional views showing a comparative display panel manufacturing method;

FIG. 18 is an equivalent circuit diagram showing another example of the circuit configuration of the pixels arranged in the display panel according to the embodiment;

FIG. 19 is a plan layout view showing the other example of a pixel applicable to the embodiment;

FIGS. 20A and 20B are perspective views showing the configuration of a digital camera according to an application of the embodiment;

FIG. 21 is a perspective view showing the configuration of a mobile personal computer according to the application of the embodiment; and

FIG. 22 is a diagram showing the configuration of a mobile telephone according to the application of the embodiment.

### DETAILED DESCRIPTION OF THE INVENTION

Hereinafter, a thin film transistor array substrate, a light-emitting panel, and a manufacturing method thereof as well as an electronic device according to an embodiment will be described in detail. First, the light-emitting panel to which the thin film transistor array substrate according to the embodiment is applied and the manufacturing method thereof are described. Here, a display panel in which pixels having organic EL elements are arranged is shown and described as the light-emitting panel to which the thin film transistor array substrate according to the embodiment is applied.

(Light-Emitting Panel)

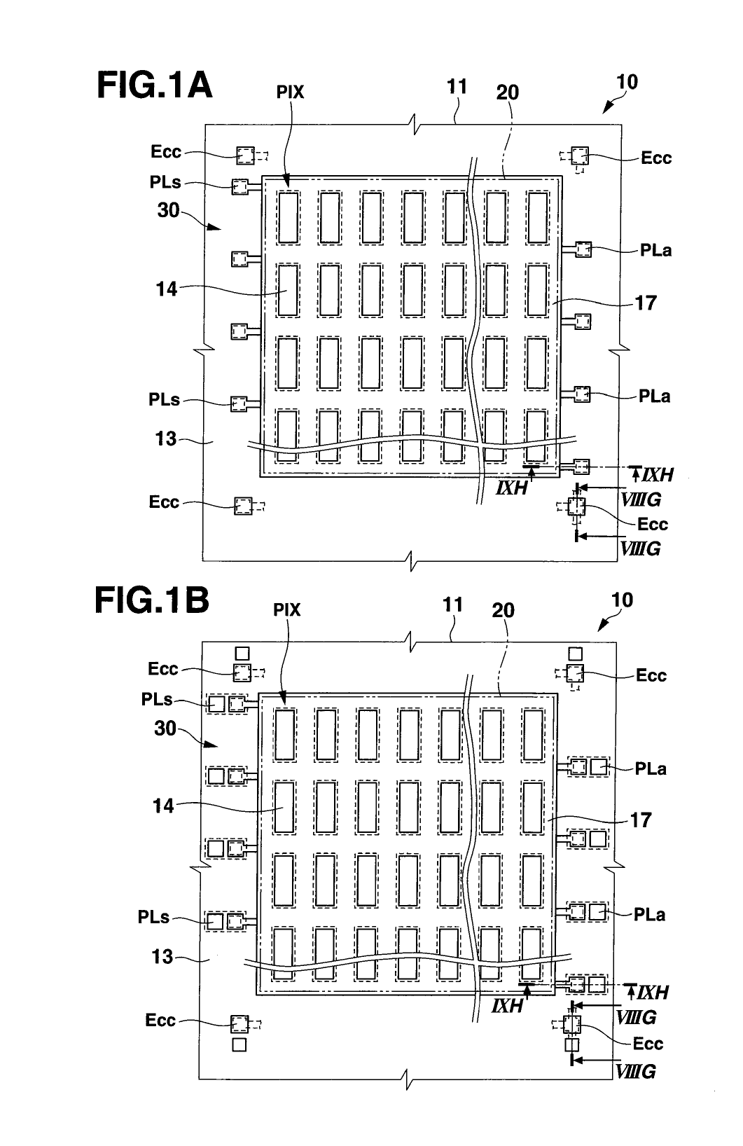

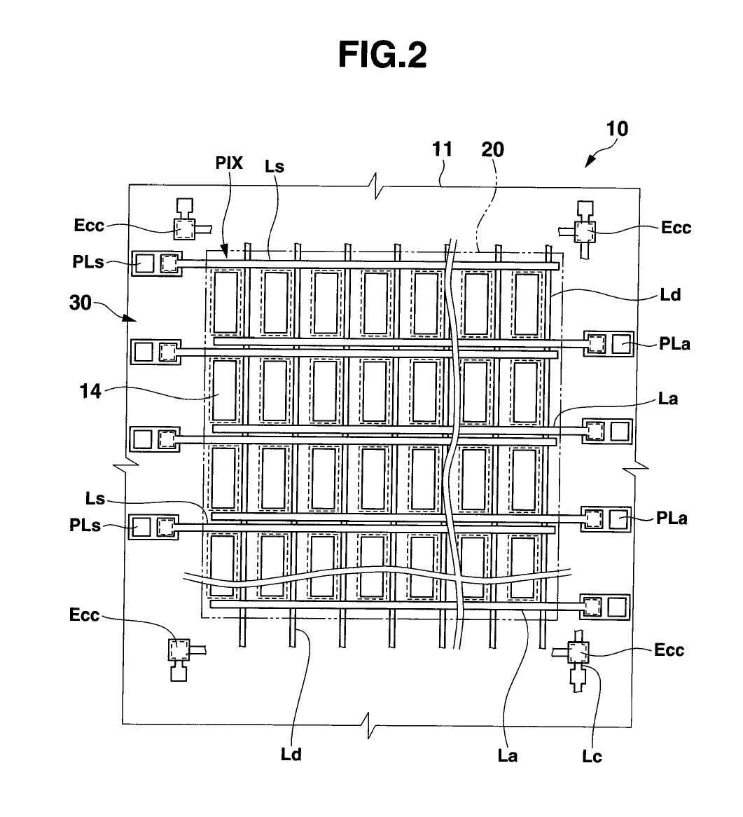

FIGS. 1A and 1B are schematic plan views showing an example of the display panel to which the thin film transistor array substrate according to the embodiment is applied. FIG. 1A is a schematic plan view showing a first example of the display panel, and FIG. 1B is a schematic plan view showing a second example of the display panel. FIG. 2 is a schematic plan view showing one example of how the pixels are arranged and how a wiring layer is provided in the display panel shown in FIG. 1B.

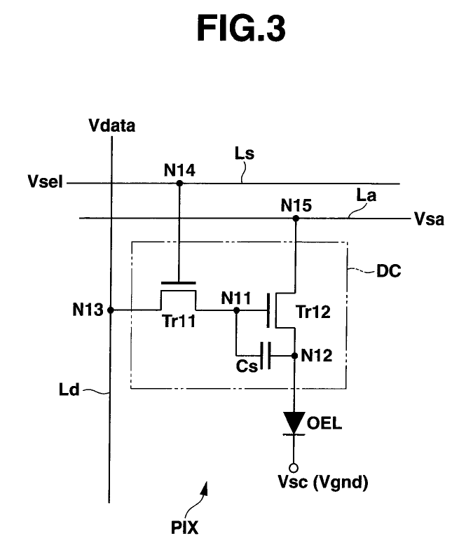

Here, for convenience of explanation, FIG. 1 only show the plan views, from one side of the display panel (the side of the substrate where the organic EL elements are formed), of pixel electrodes of the pixels in a display area, openings provided in a partition layer defining areas where the pixels (or light-emitting elements) are formed, and the location of external connection terminal pads provided in a peripheral area outside the display area. The plan view of FIG. 2 only shows the relation of arrangement between the pixel electrodes of the pixels and the wiring layers, and does not show the transistors and the like provided in a light emission drive circuit (see FIG. 3 described later) for driving the organic EL elements (light-emitting elements) of the pixels to emit light. In FIGS. 1A, 1B, and 2, the pixel electrodes, the wiring layer, the terminal pads and the partition layer are hatched for convenience to clearly show how these components are arranged or covered.

For example, as shown in FIGS. 1A, 1B, and 2, a display area 20 and a peripheral area 30 therearound are set on one side of (near side of the drawings) of a transparent substrate 11 such as a glass substrate in a display panel (light-emitting panel) 10 to which the thin film transistor array substrate according to the embodiment is applied. In the display area 20, pixels PIX are arranged in matrix form in a row direction (lateral direction of the drawing) and in a column direction (longitudinal direction of the drawing).

Here, for example, as shown in FIG. 2, data lines Ld are laid in the column direction around pixel electrodes 14 provided in the pixels PIX. Further, select lines Ls and power supply voltage lines (e.g., anode line) La are laid in the row direction perpendicular to the data lines Ld. Terminal pads PLs are provided on one ends of the select lines Ls, and terminal pads PLa are provided on one ends of the power supply voltage lines La. Unshown terminal pads are also provided on one ends of the data lines Ld. Although described in detail later, an opposed electrode (e.g., a cathode electrode) comprising a single electrode layer (solid electrode) is formed in the display panel 10 so that the pixel electrodes 14 arranged on the substrate 11 face this common opposed electrode.

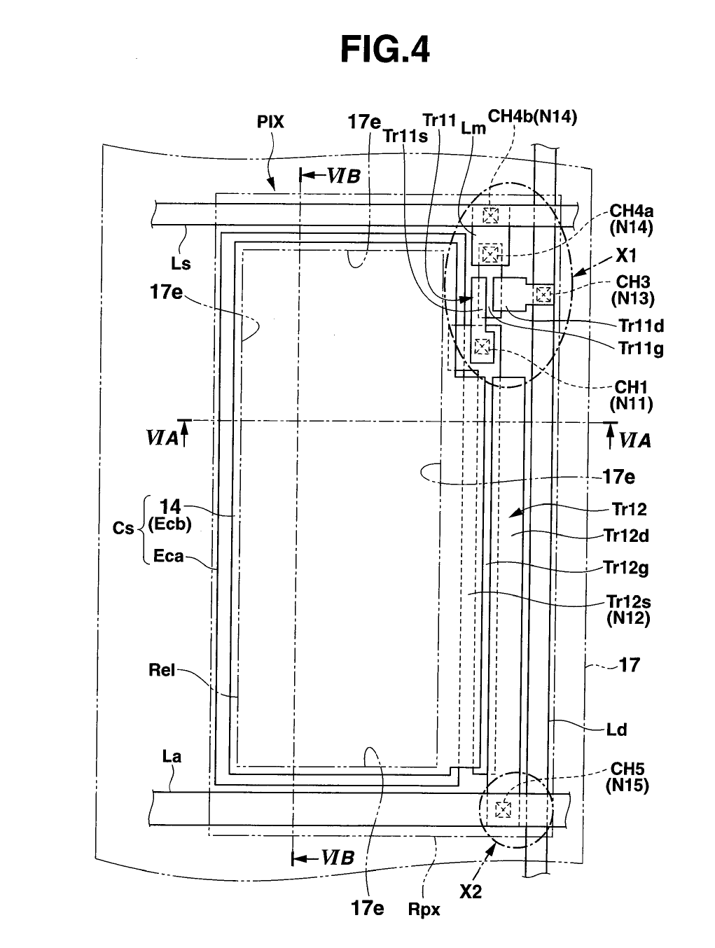

Further splay area 20 of the panel 10, a partition 17 is provided in an area including a boundary area between at least the pixel electrodes 14 of the pixels PIX, as shown in FIGS. 1A and 1B. In other words, openings for exposing at least the pixel electrodes 14 of the pixels PIX are provided in the partition layer 17 which is formed in the area including the display area 20. The area which is enclosed by the partition layer 17 and which exposes a pixel electrode (e.g., anode electrode) 14 is defined as an EL element formation area for forming the organic EL element (light-emitting element) of each pixel PIX (see FIG. 4 described later). Further, the area including this EL element formation area and the partition layer 17 in the boundary area around the EL element formation area are defined as a pixel formation area for each pixel PIX (see FIG. 4 described later).

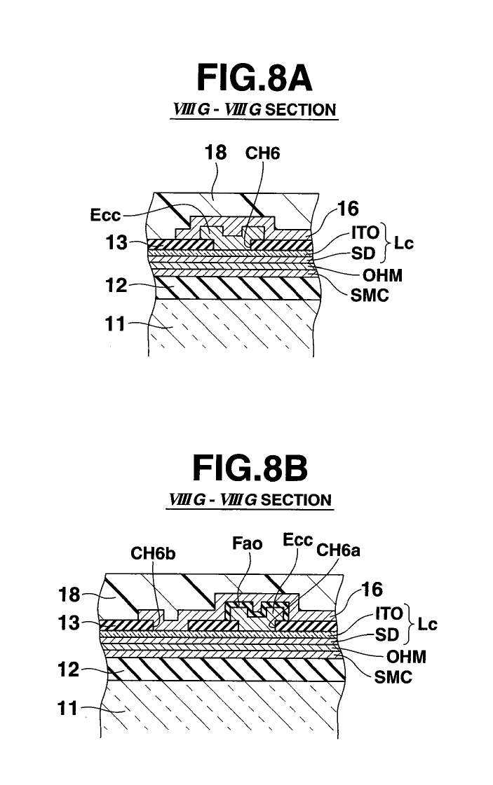

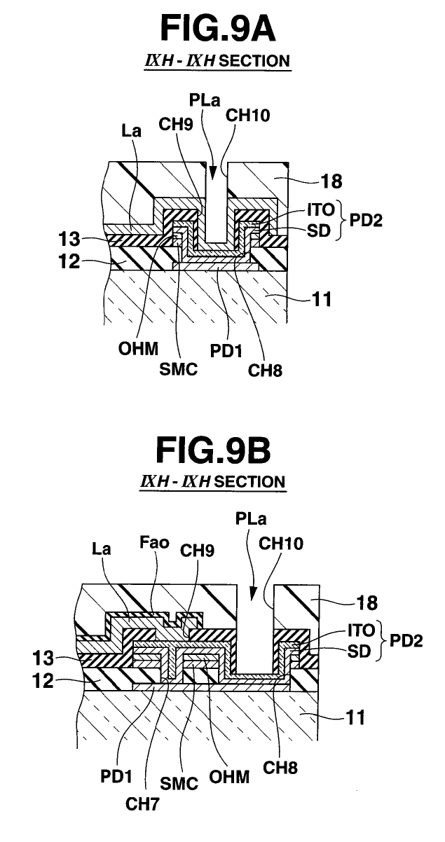

On the other hand, in the peripheral area 30 of the display panel 10, there are arranged, at predetermined positions, the terminal pads PLs, PLa connected to the select lines Ls and the power supply voltage lines La, the terminal pads (not shown) connected to the data lines Ld, and contact electrodes Ecc to which the opposed electrode (e.g., cathode electrode) is connected. The terminal pads PLs, PLa (including the terminal pad connected to the data line Ld) are electrically connected to, for example, unshown flexible substrate and driver IC outside the display panel, and are supplied with a predetermined drive signal and a drive voltage. The display panel 10 shown in FIGS. 1A and 1B has different structures to serve as the terminal pads PLs, PLa and the contact electrodes Ecc arranged in the peripheral area 30. Details of these structures will be described later (see FIGS. 8A, 8B, 9A, and 9B). However, any of these structures may be applied to the display panel 10 according to the embodiment.

(Pixels)

FIG. 3 is an equivalent circuit diagram showing an example of the circuit configuration of each of the pixels (the light-emitting elements and the light emission drive circuits) arranged in the display panel according to this embodiment.

Each pixel PIX includes, for example, as shown in FIG. 3, a light emission drive circuit DC and an organic EL element (light-emitting element) OEL. The light emission drive circuit DC has a circuit configuration including one or more transistors (e.g., amorphous silicon thin film transistors). The organic EL element OEL is supplied with a light emission drive current controlled by the light emission drive circuit DC, and thereby emits light.

More specifically, the light emission drive circuit DC includes a transistor Tr11, a transistor (drive transistor) Tr12, and a capacitor Cs, for example, as shown in FIG. 3. The transistor Tr11 has its gate terminal connected to the select line Ls through a contact N14, its drain terminal connected to the data line Ld through a contact N13, and its source terminal connected to a contact N11. The transistor Tr12 has its gate terminal connected to the contact N11, its drain terminal connected to a power supply voltage line La through a contact N15, and its source terminal connected to a contact N12. The capacitor Cs is connected between the gate terminal (contact N11) and source terminal (contact N12) of the transistor Tr12.

Here, the transistors Tr11, Tr12 both comprise n-channel type thin film transistors. If the transistors Tr11, Tr12 are p-channel type transistors, their source terminals and drain terminals are reversed. Moreover, the capacitor Cs is a parasitic capacitance formed between the gate and source of the transistor Tr12, or a storage capacitance additionally provided between the gate and source of the transistor Tr12, or a capacitance component comprising the parasitic capacitance and the storage capacitance.

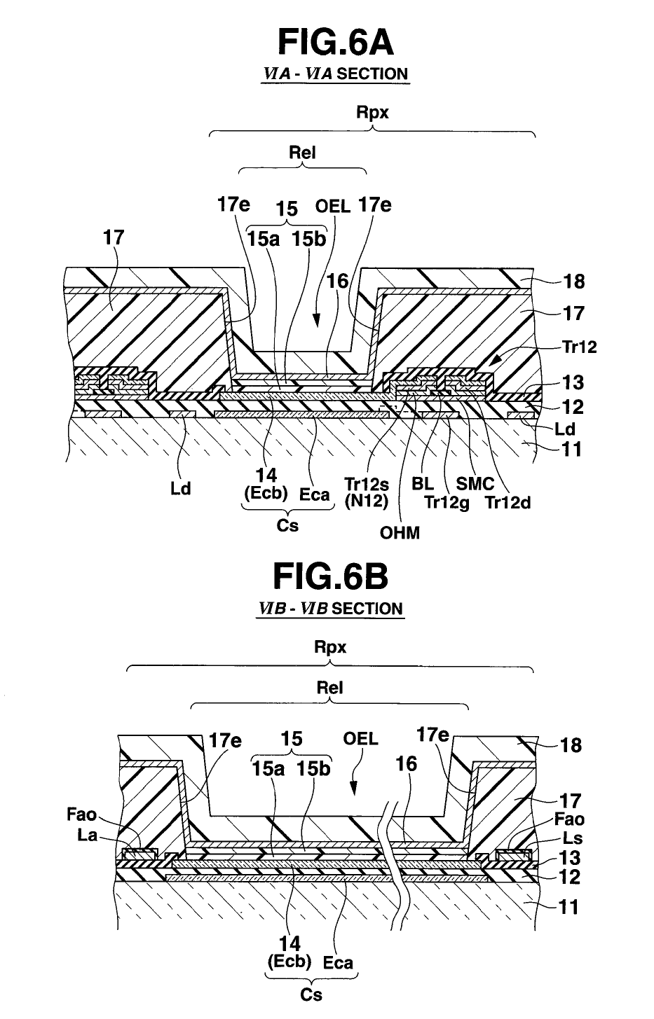

Furthermore, the organic EL element OEL has its anode (the pixel electrode 14 serving as an anode electrode) connected to the contact N12 of the light emission drive circuit DC, and its cathode (opposed electrode 16 serving as a cathode electrode; see FIGS. 6A and 6B described later) directly or indirectly connected to, for example, a predetermined low-potential power supply through a contact electrode Ecc. Therefore, the opposed electrode 16 serving as a cathode electrode is configured by the single electrode layer (solid electrode) so that the pixel electrodes 14 arranged on the substrate 11 face this common opposed electrode. Thus, a predetermined common low voltage (reference voltage Vsc; e.g., ground potential Vgnd) is applied to, for example, all the pixels PIX (organic EL elements OEL).

In the pixel PIX (the light emission drive circuit DC and the organic EL element OEL) shown in FIG. 3, the select line Ls is connected to an unshown select driver through the terminal pad PLs shown in FIGS. 1A, 1B, and 2. The select driver applies, to the select line Ls, a select voltage Vsel for setting the pixel PIX to a selected state by predetermined timing. Moreover, the data line Ld is connected to a data driver through an unshown connection pad. The data driver applies, to the data line Ld, a gradation voltage Vdata corresponding to image data by timing synchronous with the selected state of the pixel PIX.

Furthermore, the power supply voltage line La is directly or indirectly connected to, for example, a predetermined high-potential power supply through a terminal pad PLa shown in FIGS. 1A, 1B, and 2. Here, a predetermined high voltage (power supply voltage Vsa) is applied to the power supply voltage line La. This high voltage enables a light emission drive current corresponding to the image data to be passed through the pixel electrode (anode electrode) 14 of the organic EL element OEL provided in each pixel PIX. This high voltage is set at a voltage higher in potential than the reference voltage Vsc applied to the opposed electrode 16 of the organic EL element OEL.

The drive control operation in the pixel PIX having such a circuit configuration is as follows: First, the select voltage Vsel at a select level (e.g., high level) is applied to the select line Ls from the unshown select driver during a predetermined select period. Accordingly, the transistor Tr11 provided in the light emission drive circuit DC turns on, and the pixel PIX is set to the selected state. Synchronously with this timing, the gradation voltage Vdata corresponding to image data is applied to the data line Ld from the unshown data driver. Thus, the contact N11 (i.e., the gate terminal of the transistor Tr12) is connected to the data line Ld through the transistor Tr11, and a potential corresponding to the gradation voltage Vdata is applied to the contact N11.

Here, the value of a current across the drain and source of the transistor Tr12 (i.e., the light emission drive current running through the organic EL element OEL) is determined by a potential difference between the drain and source and by a potential difference between the gate and source. That is, it the light emission drive circuit DC shown in FIG. 3, the value of the current running across the drain and source of the transistor Tr12 can be controlled by the gradation voltage Vdata.

Therefore, the transistor Tr12 turns on in a conducting state corresponding to the potential (i.e., the gradation voltage Vdata) of the contact N11, so that the light emission drive current having a predetermined value runs to the low-potential-side reference voltage Vsc (the ground potential Vgnd) from the high-potential-side power supply voltage Vsa through the transistor Tr12 and the organic EL element OEL. Accordingly, the organic EL element OEL emits light with a luminance gradation corresponding to the gradation voltage Vdata (i.e., the image data). At the same time, a charge is accumulated in the capacitor Cs between the gate and source of the transistor Tr12 (the capacitor Cs is charged) in accordance with the gradation voltage Vdata applied to the contact N11.

Furthermore, during an unselect period after the select period described above, the select voltage Vsel at an unselect level (off level; e.g., low level) is applied to the select line Ls from the select driver. Accordingly, the transistor Tr11 of the light emission drive circuit DC turns off and is set to an unselected state, and the data line Ld and the contact N11 are electrically disconnected from each other. At the same time, the charge accumulated in the capacitor Cs is maintained, so that the potential difference between the gate and source of the transistor Tr12 is maintained, and a voltage corresponding to the gradation voltage Vdata is applied to the gate terminal (contact N11) the transistor Tr12.

Thus, as in the selected state described above, the light emission drive current having a value substantially equal to that in a light emitting state runs to the organic EL element DEL from the power supply voltage Vsa through the transistor Tr12, and the light emitting state continues. This light emitting state is controlled to continue for, for example, one-frame period before the gradation voltage Vdata corresponding to the next image data is written. Such drive control operation is sequentially performed row by row for all the pixels PIX two-dimensionally arranged in the display panel 10, thereby performing the operation of displaying predetermined image information.

(Device Structure of Pixel)

Now, a detailed device structure (plan layout and sectional structure) of the pixel (the light emission drive circuit and the organic EL element) having the above-described circuit configuration is described. Here, there is shown an organic EL, display panel having a bottom emission type light emission structure which radiates light generated in the organic. EL layer to a visual field side (the other side of the substrate) through the substrate.

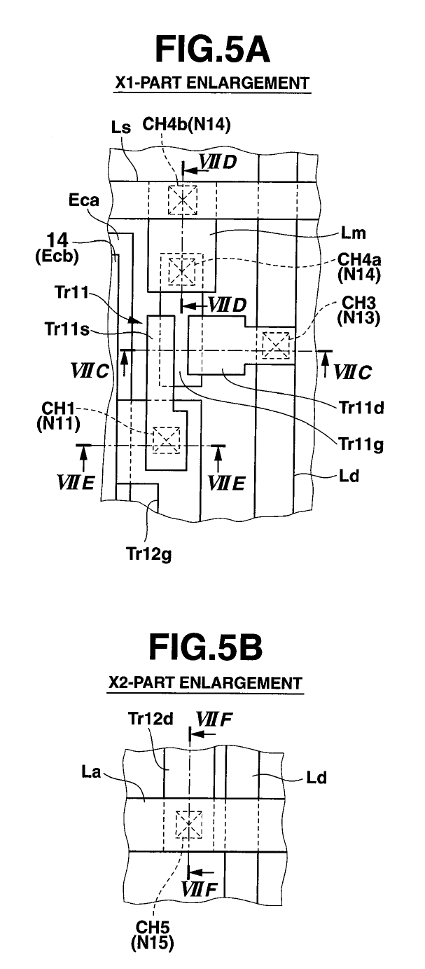

FIG. 4 is a plan layout view showing an example of a pixel applicable to the embodiment. FIGS. 5A and 5B are enlarged views of essential parts of the pixel according to the embodiment. In FIGS. 4, 5A, and 5B, the layer in which the transistors and wirings of the light emission drive circuit DC shown in FIG. 3 are formed is mainly shown. The electrodes and the wiring layer in the transistors, and the pixel electrodes are hatched for convenience for clarity.

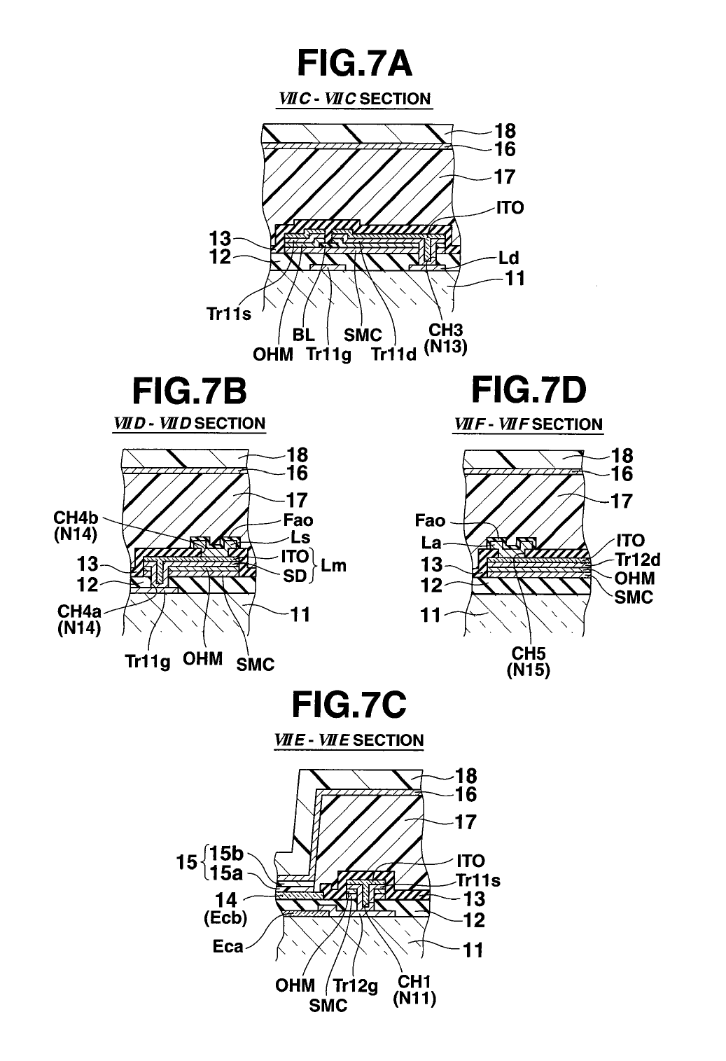

Moreover, FIGS. 6A, 6B, 7A, 7B, 7C, 7D, 8A, 8B, 9A, and 9B are sectional views of essential parts of the display panel according to the embodiment. Here, FIGS. 6A and 6B are schematic sectional views showing sections taken along the line VIA-VIA (“VI” is used for convenience in the present specification as a sign corresponding to a Roman numeral “6” shown in FIG. 4. The same will hereinafter hold true.) and the line VIB-VIB in the pixel having the plan layout shown in FIG. 4, respectively. FIGS. 7A, 7B, 7C, and 7D are schematic sectional views showing sections taken along the line VIIC-VIIC (“VII” is used for convenience in the present specification as a sign corresponding to a Roman numeral “7” shown in FIGS. 5A and 5B. The same will hereinafter hold true.), the line VIID-VIID, the line VIIE-VIIE, and the line VIIF-VIIF in the plan layout of the essential parts shown in FIGS. 5A and 5B, respectively. FIGS. 8A and 8B are schematic sectional views showing a section taken along the line VIIIG-VIIIG (“VIII” is used for convenience in the present specification as a sign corresponding to a Roman numeral “8” shown in FIGS. 1A and 1B. The same will hereinafter hold true.) in the display panel having the plan layout shown in FIGS. 1A and 1B, respectively. FIGS. 9A and 9B are schematic sectional views showing a section taken along the line IXH-IXH (“IX” is used for convenience in the present specification as a sign corresponding to a Roman numeral “9” shown in FIGS. 1A and 1B. The same will hereinafter hold true.) in the display panel having the plan layout shown in FIGS. 1A and 1B, respectively.

More specifically, as shown in FIGS. 6A and 6B, the pixel PIX shown in FIG. 4 is provided for each pixel formation area Rpx set on one side of the substrate 11 (upper side of the drawings). In this pixel formation area Rpx, at least a formation area for the organic EL element OEL (EL element formation area) Rel and a boundary area between adjacent pixels PIX are set.

In areas at the upper and lower edges of the pixel formation area Rpx in the diagram shown in FIG. 4, the select line Ls and the power supply voltage line La are respectively provided to extend in the row direction (lateral direction of the drawing). On the other hand, in an area at the right edge of the pixel formation area Rpx in the diagram, the data line Ld is provided to extend in the column direction (longitudinal direction of the drawing) perpendicularly to the select line Ls and the power supply voltage line La.

Furthermore, in boundary areas set at the upper, lower, right and left edge areas of the pixel formation area Rpx, the partition layer 17 is formed across the pixel formation areas Rpx of the pixels PIX adjacently arranged in the longitudinal and lateral directions, as shown in FIGS. 4, 6A, and 6B. Thus, an area which is surrounded by sidewalls 17e of the partition layer 17 and which exposes the pixel electrode 14 is defined as the EL element formation area Rel.

The data line Ld is provided on a side (substrate 11 side) lower than the select line Ls and the power supply voltage line La, for example, as shown in FIGS. 4, 5A, 5B, 6A, 6B, and 7A. The data line Ld is formed in the same process as gate electrodes Tr11g, Tr12g of the transistors Tr11, Tr12 by patterning a gate metal layer for forming these gate electrodes Tr11g, Tr12g. As shown in FIGS. 4 and 7A, the data line Ld is connected to a drain electrode Tr11d of the transistor Tr11 through a contact hole CH3 (corresponding to the contact N13) provided in a gate insulating film 12 which is formed over the data line Ld. Here, as shown in FIGS. 6A and 7A, the gate insulating film 12, an insulating film 13, and the partition layer 17 intervene between the data line Ld and the opposed electrode 16, so that the parasitic capacitance can be reduced, and the delay of the signal (gradation voltage Vdata) supplied to the data line Ld can be suppressed.

Furthermore, for example, as shown in FIGS. 4, 5A, 5B, 6A, 6B, 7B, and 7D, the select line Ls and the power supply voltage line La are provided in a layer higher than source electrodes Tr11s, Tr12s and drain electrodes Tr11d, Tr12d of the transistors Tr11 and Tr12. The select line Ls and the power supply voltage line La are made of, for example, an aluminum alloy material containing several weight percent of one or two kinds of high melting point metals or rare-earth elements. In particular, in the embodiment, at least the surface layer of the power supply voltage line La is covered with and insulated by an insulating film Fao comprising an anodic oxide film, for example, as shown in FIGS. 6B and 7D. In the panel structure according to the embodiment, the surface layer of the select line Ls is also covered with and insulated by the insulating film Fao comprising an anodic oxide film, for example, as shown in FIGS. 6B and 7B.

Moreover, as shown in FIGS. 4, 5A, and 7B, the select line Ls is connected to an intermediate layer Lm through a contact hole CH4a provided in the underlayer insulating film 13. The intermediate layer Lm is electrically connected to the gate electrode Tr11g of the transistor Tr11 through a contact hole CHb provided in the further lower gate insulating film 12. The intermediate layer Lm has a configuration in which source/drain metal layer SD configuring the later-described transistors Tr11, Tr12 and a transparent electrode layer ITO configuring the organic EL element OEL are stacked. A semiconductor layer SMC and an impurity layer OHM are provided in a layer under the intermediate layer Lm. As shown in FIGS. 4, 5B, and 7D, the power supply voltage line La is electrically connected to the drain electrode Tr12d of the transistor Tr12 through a contact hole CH5 provided in the underlayer insulating film 13.

Here, for example, titanium (Ti), tantalum (Ta), zirconium (Zr), tungsten (W), or molybdenum (Mo) can be advantageously used as the high melting point, metal contained in the aluminum alloy that forms the select line Ls and the power supply voltage line La. More specifically, an aluminum alloy such as Al—Ti (0.5% to 1.5%), Al—Ta (1.0% to 2.0%), Al—Zr (0.5% to 3%), Al—W (1.0% to 2.0%), or Al—Mo (0.5% to 1.5%) can be used as a wiring material for the select line Ls and the power supply voltage line La. The numbers in the parentheses indicate the weight percentages of the high melting point metals contained in aluminum. For example, neodymium (Nd), gadolinium (Gd), or scandium (Sc) can be advantageously used as the rare-earth element contained in the aluminum alloy that forms the select line Ls and the power supply voltage line La. More specifically, an aluminum alloy such as Al—Sc (0.5% to 2.5%) can be used as a wiring material for the select line Ls and the power supply voltage line La.

Such select line Ls and power supply voltage line La extend on one end to the peripheral area 30 outside the display area 20 and are connected to the terminal pads PLs, PLa, as shown in FIGS. 1A, 1B and 2. A first example of the terminal pad PLa connected to the power supply voltage line La is specifically shown. For example, as shown in FIG. 9A, the power supply voltage line La is electrically connected to an upper pad layer PD2 through a contact hole CH9 provided in the insulating film 13. Here, the surface layer of the power supply voltage line La is not covered with the insulating film Fao comprising an anodic oxide film. In order to obtain such a terminal structure, the power supply voltage line La located in the vicinity of the terminal pad PLa is covered with, for example, a resist in advance to allow no exposure, and is they anodically oxidized in this state so that its surface layer may not be an insulating film, in the later-described display panel manufacturing method. Similarly to the above-mentioned intermediate layer Lm, the upper pad layer PD2 has a configuration in which the source/drain metal layer SD configuring the later-described transistors Tr11, Tr12 and the transparent electrode layer ITO configuring the organic EL element OEL are stacked. A semiconductor layer SMC and an impurity layer OHM are provided in a layer under the upper pad layer PD2. The upper pad layer PD2 is electrically connected to an underlayer lower pad layer PD1 through a contact hole CH8 provided in the impurity layer OHM, the semiconductor layer SMC, and the gate insulating film 12. Here, similarly to the above-mentioned data line Ld, the lower pad layer PD1 is formed by a gate metal layer that configures the transistors Tr11, Tr12.

Furthermore, a second example of the terminal pad PLa is specifically shown. For example, as shown in FIG. 9B, the power supply voltage line La is electrically connected to the upper pad layer PD2 through the contact hole CH9 provided in the insulating film 13. Here, the surface layer of the power supply voltage line La is covered with the insulating film Fao comprising an anodic oxide film. The upper pad layer PD2 is electrically connected to the underlayer pad layer PD1 through the contact holes CH7, CH8 provided in the impurity layer OHM, the semiconductor layer SMC, and the gate insulating film 12.

Although not shown, any one of the terminal structures shown in FIGS. 9A and 9B is applied to the terminal pad PLs (see FIGS. 1A, 1B, and 2) provided at the end of the select line Ls, similarly to the terminal pad PLa described above. Moreover, in a terminal pad (not shown) provided at the end of the data line Ld, the data line Ld is formed by a gate metal layer SD that configures the transistors Tr11, Tr12. Therefore, the end of this line is used as the lower pad layer PD1 having the terminal structures shown in FIGS. 9A and 9B. The end (lower pad layer PD1) of the data line Ld is electrically connected to the upper pad layer through the contact hole provided in the gate insulating film 12, so that a terminal structure substantially equivalent to the terminal structures shown in FIGS. 9A and 9B is applied. Here, any one of the terminal structures shown in FIGS. 9A and 9B may be applied to the terminal pads PLa, PLs (including the terminal pad provided at the end of the data line Ld).

More specifically, the transistors Tr11 and Tr12 of the light emission drive circuit DC shown in FIG. 3 are arranged to extend in the column direction (longitudinal direction of the drawing) along the data line Ld, as shown in FIG. 4. In the embodiment, the width direction of the channels of the transistors Tr11, Tr12 is set to be parallel to the data line Ld.

Here, each of the transistors Tr11, Tr12 has the structure of a known field-effect thin film transistor. That is, as shown in FIGS. 4, 6A, and 7A, the transistors Tr11, Tr12 have the gate electrodes Tr11g, Tr12g, the semiconductor layer SMC formed in areas corresponding to at least the gate electrodes Tr11g, Tr12g through the gate insulating film 12, and the source electrodes Tr11s, Tr12s and drain electrodes Tr11d, Tr12d formed to extend at both ends of the semiconductor layer SMC.

As shown in FIGS. 6A and 7A, the transparent electrode layer ITO configuring the pixel electrode 14 of the later-described organic EL element OEL is formed in an aligning manner on the source electrodes Tr11s, Tr12s and drain electrodes Tr11d, Tr12d of the transistors Tr11, Tr12. Moreover, the impurity layer OHM is formed between at least the source electrodes Tr11s, Tr12s and drain electrodes Tr11d, Tr12d, and the semiconductor layer SMC. The impurity layer OHM is formed by, for example, an n+ silicon layer comprising amorphous silicon that contains an n-type impurity, and has a function of obtaining an ohmic connection between the semiconductor layer SMC and the source electrodes Tr11s, Tr12s and drain electrodes Tr11d, Tr12d. The display panel 10 in the embodiment has a substrate structure formed by the impurity layer OHM and the semiconductor layer SMC that extend under the source electrodes Tr11s, Tr12s and the drain electrodes Tr11d, Tr12d and under the wiring layer formed simultaneously with these electrodes. A channel protecting layer BL is formed on the semiconductor layer SMC on which the source electrodes Tr11s, Tr12s and drain electrodes Tr11d, Tr12d of the transistors Tr11, Tr12 face each other. The channel protecting layer BL is made of, for example, silicon oxide or silicon nitride, and has a function of preventing an etching damage to the semiconductor layer SMC.

In accordance with the circuit configuration of the light emission drive circuit DC shown in FIG. 3, the gate electrode Tr11g of the transistor Tr11 is connected to the select line Ls through a contact hole CH4b provided in the gate insulating film 12, through the intermediate layer Lm, and through a contact hole CH4a provided in the insulating film 13, as shown in FIGS. 4, 5A, and 7B. The drain electrode Tr11d of the transistor Tr11 is connected to the data line Ld through the contact hole CH3 provided in the gate insulating film 12, as shown in FIGS. 4, 5A, and 7A. The source electrode Tr11s of the transistor Tr11 is connected to the gate electrode Tr12g of the transistor Tr12 through a contact hole CH1 provided in the gate insulating film 12, as shown in FIGS. 4, 5A, and 7C. Here, the contact hole CH1 corresponds to the contact N11 of the light emission drive circuit DC shown in FIG. 3. The contact hole CH3 corresponds to the contact N13. The contact holes CH4a, CH4b correspond to the contact N14.

Furthermore, the gate electrode Tr12g of the transistor Tr12 is electrically connected to the source electrode Tr11s of the transistor Tr11 through the contact hole CH1 provided in the gate insulating film 12, as shown in FIGS. 4, 5A, 6A, and 7C. The gate electrode Tr12g is directly connected to a lower electrode Eca of the capacitor Cs. The drain electrode Tr12d of the transistor Tr12 is electrically connected to the power supply voltage line La through the contact hole CH5 provided in the insulating film 13, as shown in FIGS. 4, 5B, and 7D. The source electrode Tr12s of the transistor Tr12 is directly connected to the pixel electrode 14 of the organic EL element OEL that also serves as an upper electrode Ecb of the later-described capacitor Cs, as shown in FIGS. 4 and 6A. Here, the contact hole CH1 corresponds to the contact N11 of the light emission drive circuit DC shown in FIG. 3. The contact hole CH5 corresponds to the contact N15. A connection point, of the source electrode Tr12s and the pixel electrode 14 (upper electrode Ecb) corresponds to the contact N12 of the light emission drive circuit DC shown in FAG. 3.

As shown in FIGS. 4, 6A, and 6B, the capacitor Cs has the lower electrode Eca, the upper electrode Ecb facing the lower electrode Eca, and the gate insulating film 12 intervening between the lower electrode boa and the upper electrode Ecb. Here, the gate insulating film 12 also serves as a dielectric layer of the capacitor Cs. The upper electrode Ecb also serves as the pixel electrode 14 of the later-described organic EL element OEL. That is, the capacitor Cs is provided under the organic EL element OEL (on the side of the substrate 11).

As shown in FIGS. 4, 6A, and 6B, the organic EL element OEL has an element structure in which the pixel electrode (anode electrode) 14, an organic EL layer (light-emitting function layer) 15, and the opposed electrode (cathode electrode) 16 are sequentially stacked. The pixel electrode 14 is provided on the gate insulating film 12 of the transistors Tr11, Tr12, and also serves as the upper electrode Ecb of the capacitor Cs, as described above. Moreover, the pixel electrode 14 partly extends to be directly connected to the source electrode Tr12s of the transistor Tr12, and is thus supplied with the predetermined light emission drive current from the light emission drive circuit DC.

As shown in FIGS. 4, 6A, and 6B, the organic EL layer 15 is formed on the pixel electrode 14 that is exposed in the EL element formation area Rel defined by the sidewalls 17e of the partition layer 17 formed on the substrate 11. The organic EL layer 15 is constituted of, for example, a hole injection layer (or a hole transport layer including a hole injection layer) 15a and an electron transport light-emitting layer 15b. The organic EL layer 15 referred to here is an organic EL layer in which a layer functioning as a light-emitting layer among carrier transport layers such as the hole injection layer, the light-emitting layer and an electron injection layer is made of an organic material.

The opposed electrode 16 is provided so that the pixel electrodes 14 of the pixels PIX two-dimensionally arranged on the substrate 11 face this common opposed electrode. The opposed electrode 16 is formed by a single electrode layer (solid electrode) to correspond to, for example, the display area 20 of the substrate 11. The opposed electrode 16 is provided to extend not only in the EL element formation area Rel of the pixels PIX but also on the partition layer 17 that defines the EL element formation area Rel and on the insulating film 13. Moreover, the opposed electrode 16 is provided to partly extend to the peripheral area 30 outside the display area 20, and is electrically connected to a cathode line Lc through the contact electrode Ecc disposed in the peripheral area 30. A first example of this cathode contact portion is specifically shown. For example, as shown in FIG. 8A, the opposed electrode 16 is electrically connected to the contact electrode Ecc. The contact electrode Ecc is electrically connected to the cathode line Lc in a layer under the insulating film 13 through a contact hole CH6 provided in the insulating film 13. Here, the surface layer of the contact electrode Ecc is not covered with the insulating film Fao comprising an anodic oxide film. That is, in this case as well, in the later-described display panel manufacturing method, the contact electrode Ecc is covered with, for example, a resist in advance to allow no exposure, and is then anodically oxidized in this state so that its surface layer may not be an insulating film.

Furthermore, a second example of the cathode contact portion is specifically shown. For example, as shown in FIG. 8B, the opposed electrode 16 is electrically connected to the contact electrode Ecc, and is directly connected to the cathode line Lc in a layer under the insulating film 13 through a contact hole CH6b provided in the insulating film 13. The contact electrode Ecc is connected to the cathode line Lc through a contact hole CH6a provided in the insulating film 13. Here, the surface layer of the contact electrode Ecc is covered with the insulating film Fao comprising an anodic oxide film.

As a result, the predetermined reference voltage Vsc (cathode voltage; e.g., the ground potential Vgnd) is applied to the opposed electrode 16 through a connection pad (not shown) connected to the contact electrode Ecc and the cathode line Lc. Here, the cathode line Lc has a configuration in which the source/drain metal layer SD configuring the above-mentioned transistors Tr11, Tr12 and the transparent electrode layer ITO configuring the organic EL element OEL are stacked. Under this layer, the semiconductor layer SMC and the impurity layer OHM extend in an aligning manner.

Any one of the connection structures of the cathode contact portion shown in FIGS. 8A and 8B may be applied. Any combination of structures may be applied including the above-mentioned terminal structures of the terminal pad (see FIGS. 9A and 9B).

Furthermore, the end of the connection pad (not shown) provided at the end of the cathode line Lc is applied as the upper pad layer PD2 of the terminal structures shown in FIGS. 9A and 9B because the cathode line Lc is formed by the source/drain metal layer SD configuring the transistors Tr11, Tr12. The end (upper pad layer PD2) of the cathode line Lc is electrically connected to the lower pad layer PD1 through the contact hole provided in the gate insulating film 12, so that a terminal structure substantially equivalent to the terminal structures in FIGS. 9A and 9B is applied.

Here, since the display panel 10 according to the embodiment has the bottom emission type light emission structure, the pixel electrode 14 is made of a transparent electrode material having a high light transmittance such as indium thin oxide (ITO). On the other hand, the opposed electrode 16 includes an electrode material having a high light reflectance such as simple aluminum (Al) or an aluminum alloy.

As shown in FIGS. 1A, 1B, 6A, and 6B, the partition layer 17 is provided at least in a lattice form in the boundary area of the pixels PIX two-dimensionally arranged in the display panel 10. Here, the partition layer 17 is made of an insulating material that can be patterned by, for example, a dry etching method, such as a polyimide resin material which is a photosensitive insulating material.

As shown in FIGS. 1A, 1B, 6A, 6B, 7A, 7B, 7C, 7D, 8A, 8B, 9A, and 9B, the insulating film 13 is provided substantially all over the substrate 11. As shown in FIGS. 6A, 6B, 7A, 7B, 7C, and 7D, the insulating film 13 is provided on the substrate 11 to cover at least the boundary area of the pixels PIX. Thus, in the display area 20, the transistors Tr11, Tr12 and the wiring layer formed by the source/drain metal layer that configures the source electrodes Tr11s, Tr12s and the drain electrodes Tr11d, Tr12d of the transistors Tr11, Tr12 are covered with the insulating film 13 and the partition layer 17. Moreover, in the peripheral area 30, the wiring layer formed by the source/drain metal layer SD is covered with the insulating film 13.

Furthermore, on one side of the substrate 11 where the light emission drive circuit DC, the organic EL element OEL (the pixel electrode 14, the organic EL layer 15, the opposed electrode 16), the insulating film 13, and the partition layer 17 are formed, a sealing layer 18 is formed to seal the display panel 10. Here, in the peripheral area 30, an opening CH10 is formed in the sealing layer 18 to expose at least the terminal pads PLs, PLa, as shown in FIGS. 9A and 9B. A sealing structure in which unshown metal caps (sealing caps) or sealing substrates such as glasses are bonded together in addition to or instead of the sealing layer 18 may be applied to the display panel 10.

In the pixel PIX having the device structure described above, the light, emission drive current having a predetermined value runs across the drain and source of the transistor Tr12 and is supplied to the pixel electrode 14 in accordance with the gradation voltage Vdata corresponding to image data supplied through the data line Ld. As a result, the organic EL element OEL emits light with a desired luminance gradation corresponding to the image data.

In this case, the pixel electrode 14 of the display panel 10 has a high light transmittance, and the opposed electrode 16 has a high light reflectance (i.e., the organic EL element OEL is the bottom emission type). Thus, light generated in the organic EL layer 15 in each pixel PIX penetrates the pixel electrode 14, and then penetrates the substrate 11 directly or after reflected by the opposed electrode 16, and is finally emitted toward the other side (lower side of the diagrams of FIGS. 6A and 6B) of the substrate 11 which is the visual field side.

(Display Panel Manufacturing Method)

Now, the display panel manufacturing method according to the embodiment is described.

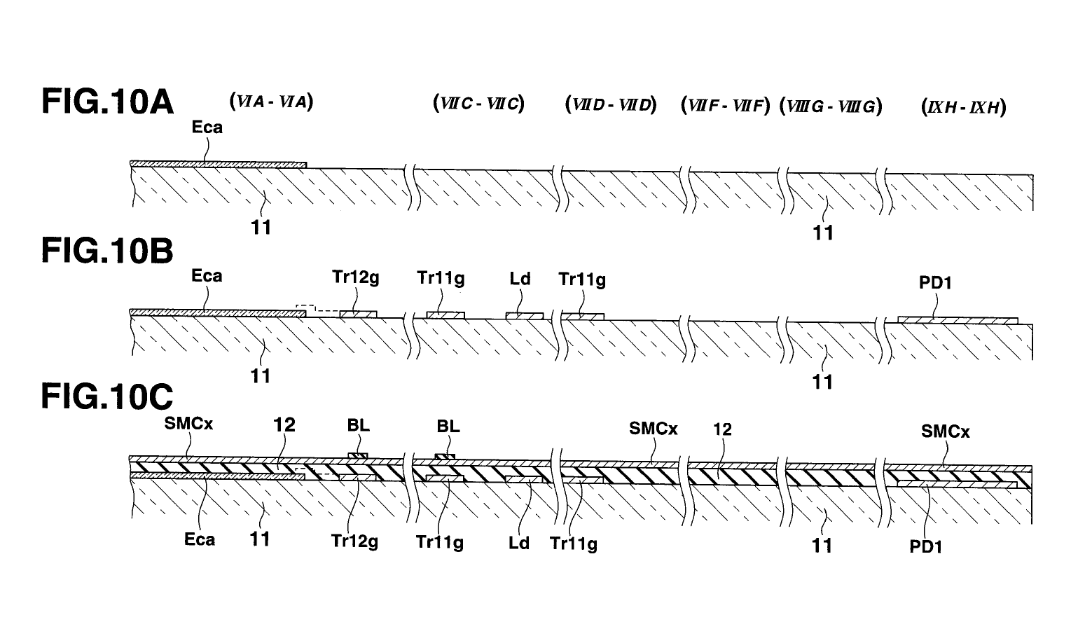

FIGS. 10A, 10B, 10C, 11A, 11B, 11C, 12A, 12B, 12C, 13A, 13B, 14A, and 14B are process sectional views showing the display panel manufacturing method according to the embodiment.

Here, for convenience of illustration, the sections of the parts of the display panel 10 shown in FIGS. 6A, 6B, 7A, 7B, 7C, 7D, 8A, 8B, 9A, and 9B are adjacently arranged. In the diagrams, (VIA-VIA), (VIB-VIB), (VIIC-VIIC), (VIID-VIID), (VIIF-VIIF), (VIIIG-VIIIG), and (IXH-IXH) show process sections in the sections shown in FIGS. 6A, 6B, 7A, 78, 7C, 7D, 8A, 8B, 9A, and 98. In the case that will be described, the terminal structure (second example) shown in FIG. 9B is applied as the terminal pad, and the connection structure (second example) shown in FIG. 8B is applied as the cathode contact portion.

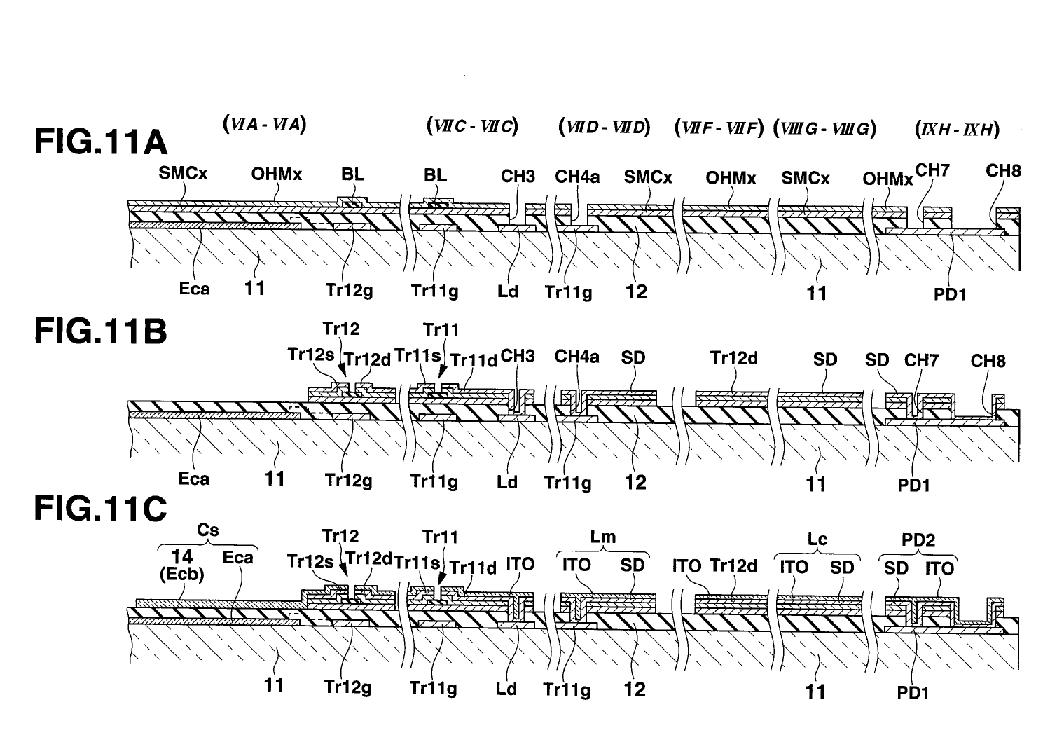

According to the above-mentioned display panel manufacturing method, transistors Tr11, Tr12 configuring the light emission drive circuit DC (see FIGS. 3 and 4), a capacitor Cs, a data line Ld, a select line Ls and a power supply voltage line La are first formed on one side of a substrate 11 such as a glass substrate, as shown in FIGS. 10A, 10B, 10C, 11A, and 11B.

More specifically, as shown in FIG. 10A, a lower electrode Eca of the capacitor Cs is first formed for each area corresponding to an EL element formation area Rel (see FIGS. 4, 6A, and 6B) in a pixel formation area Rpx for pixels PIX set on one side (upper side of the drawing) of the transparent substrate 11. Here, a transparent electrode material film having a high light transmittance such as ITO or indium zinc oxide is deposited on the substrate 11, and is then patterned by a photolithographic method, thereby forming the lower electrode Eca. Here, wet etching is used for the patterning of the transparent electrode material film.

Then, as shown in FIG. 10B, the same gate metal layer formed on one side of the substrate 11 is patterned by the photolithographic method to simultaneously form gate electrodes Tr11g, Tr12g and the data line Ld in a display area 20 except for the EL element formation area Rel. At, the same time, as shown in FIGS. 4, 5A, and 7C, one end of the gate electrode Tr12g is patterned and formed to extend onto the lower electrode Eca, so that the gate electrode Tr12g is electrically connected to the lower electrode Eca. Also, at the same time, a lower pad layer PD1 of a terminal pad PLa is formed in a peripheral area 30 of the substrate 11. Although not shown, a lower pad layer is also formed for a terminal pad PLs. Here, for example, simple molybdenum or an alloy containing molybdenum such as molybdenum-niobium (MoNb) is preferably applied to the gate metal layer for forming the gate electrodes Tr11g, Tr12g, the data line Ld and the lower pad layer PD1. Moreover, the wet etching is used for the patterning of the gate metal layer.

Then, as shown in FIG. 10C, a gate insulating film 12 made of, for example, silicon nitride, a semiconductor film SMCx made of, for example, intrinsic amorphous silicon, and an insulating film made of, for example, silicon nitride are successively formed all over the substrate 11. Further, the insulating film made of, for example, silicon nitride is patterned by the photolithographic method to form a channel protecting layer EL in an area corresponding to the gate electrodes Tr11g and Tr12g on the semiconductor film SMCx. Here, the wet etching is used for patterning the insulating film made of, for example, silicon nitride to form the channel protecting layer BL.

Then, as shown in FIG. 11A, an impurity layer OHMx made of, for example, n-type amorphous silicon is formed all over the substrate 11. Further, the impurity layer OHMx, the semiconductor film SMCx and the gate insulating film 12 are collectively patterned by the photolithographic method to expose the upper surfaces, at predetermined positions, of the data line Ld and the gate electrodes Tr11g and Tr12g of the transistors Tr11, Tr12. As a result, contact holes CH3, CH4a, and CH1 shown in FIG. 4 are formed. At the same time, contact holes CH7, CH8 are also formed which expose the upper surface, at predetermined positions, of the lower pad layer PD1 of the power supply voltage line La (although not shown, lower pad layers of the select line Ls and the data line Ld are also included) the power supply voltage line La. Here, dry etching is used for the patterning of the impurity layer OHMx, the semiconductor film SMCx, and the gate insulating film 12.

Then, as shown in FIG. 11B, a source/drain metal layer SP is formed on one side of the substrate 11. Here, the following stack structure can be applied to the source/drain metal layer: for example, a two-layer structure in which a low-resistance metal layer for reducing the wiring resistance of, for example, simple aluminum or an aluminum alloy is provided on transition metal layer for reducing the migration of, for example, chromium (Cr) or titanium (Ti); or a three-layer structure in which a metal layer of, for example, chromium is further stacked on the above-mentioned two layers. Further, the source/drain metal layer SD, the impurity layer OHMx, and the semiconductor film SMCx are collectively patterned by the photolithographic method to form source electrodes Tr11s, Tr12s and drain electrodes Tr11d, Tr12d through an impurity layer OHM for ohmic connection on at least both sides of the channel protecting layer BL or at both ends of an area serving as a semiconductor layer SMC of the transistors Tr11, Tr12. At the same time, source/drain metal layer SD serving as an underlayer of an intermediate layer Lm, a source/drain metal layer SD serving as an underlayer of a cathode line Lc, and a source/drain metal layer SD serving as an underlayer of an upper pad layer PD2 are also formed. Here, as described above, the intermediate layer Lm is a wiring layer for electrically connecting the gate electrode Tr11g of the transistor Tr11 to the select line Ls. The cathode line Lc is a wiring layer for connecting contact electrodes Ecc that are connected to an opposed electrode 16 and for supplying a predetermined reference voltage Vsc (ground potential Vgnd) to the opposed electrode 16. The upper pad layer PD2 is a wiring layer for electrically connecting the power supply voltage line La (including the select line Ls) to the lower pad layer PD1. Here, the dry etching is used for the source/drain metal layer SD, the impurity layer OHMx, and the semiconductor film SMCx.

As a result, the transistors Tr11, Tr12 of the thin film transistor structure shown in FIGS. 6A and 7A are formed. At the same time, the drain electrode Tr11d of the transistor Tr11 is electrically connected to the underlayer data line Ld through the contact hole CH3 formed in the gate insulating film 12. The source electrode Tr11s of the transistor Tr11 is electrically connected to the gate electrode Tr12g of the underlayer transistor Tr12 through the contact hole CH1 formed in the gate insulating film 12. The source/drain metal layer SD provided in the intermediate layer Lm is electrically connected to the underlayer gate electrode Tr11g through the contact hole CH4a formed in the gate insulating film 12. The source/drain metal layer SD provided in the cathode line Lc is provided to electrically connect the contact electrodes Ecc that are provided at predetermined positions of the peripheral area 30. The source/drain metal layer SD provided in the upper pad layer PD2 of the terminal pad PLa (including the terminal, pad PLs of the select line Ls and the terminal pad of the data line Ld) of the power supply voltage line La is electrically connected to the underlayer lower pad layer PD1 through the contact holes CH7, CH8 formed in the gate insulating film 12.

Then, after an electrode material film (transparent electrode layer) having a high light transmittance such as ITO or indium zinc oxide is deposited all over the substrate 11, this electrode material film is patterned by the photolithographic method to form a pixel electrode 14 having, for example, a rectangular planar pattern on at least the gate insulating film 12 in the EL element formation area Rel of each pixel PIX, as shown in FIG. 11C. In this case, the pixel electrode 14 is patterned and formed to partly extend onto the source electrode Tr12s of the transistor Tr12, so that the source electrode Tr12s is directly connected to the pixel electrode 14. Moreover, in the embodiment, a transparent electrode layer ITO for forming the pixel electrode 14 is also formed in an aligning manner on the electrodes (the source electrodes Tr11s, Tr12s and the drain electrodes Tr11d, Tr12d) comprising the above-mentioned source/drain metal layer SD and on the wiring layers (the intermediate layer Lm, the cathode line Lc and the upper pad layer PD2). Here, the wet etching is used for the patterning of the transparent electrode layer ITO.

As a result, the capacitor Cs in which the pixel electrode 14 and the lower electrode Eca are arranged to face each other through the gate insulating film 12 is formed in the EL element formation area Rel of the pixels PIX. That is, the pixel electrode 14 serves not only as an anode electrode of an organic EL element OEL but also as an upper electrode Ecb facing the to electrode Eca. The gate insulating film 12 also serves as a dielectric layer. Further, the source electrodes Tr11s, Tr12s and the drain electrodes Tr11d, Tr12d, the intermediate layer Lm, the cathode line Lc and the upper pad layer PD2 are formed which have a stack structure constituted of the source/drain metal layer SD serving as a lower layer and the transparent electrode layer ITO serving as an upper layer.

Thus, the upper electrode Ecb (pixel electrode 14) and the lower electrode Eca of the capacitor Cs are made of a transparent electrode material, so that a high aperture ratio can be obtained even in a display panel having a bottom emission type light emission structure.

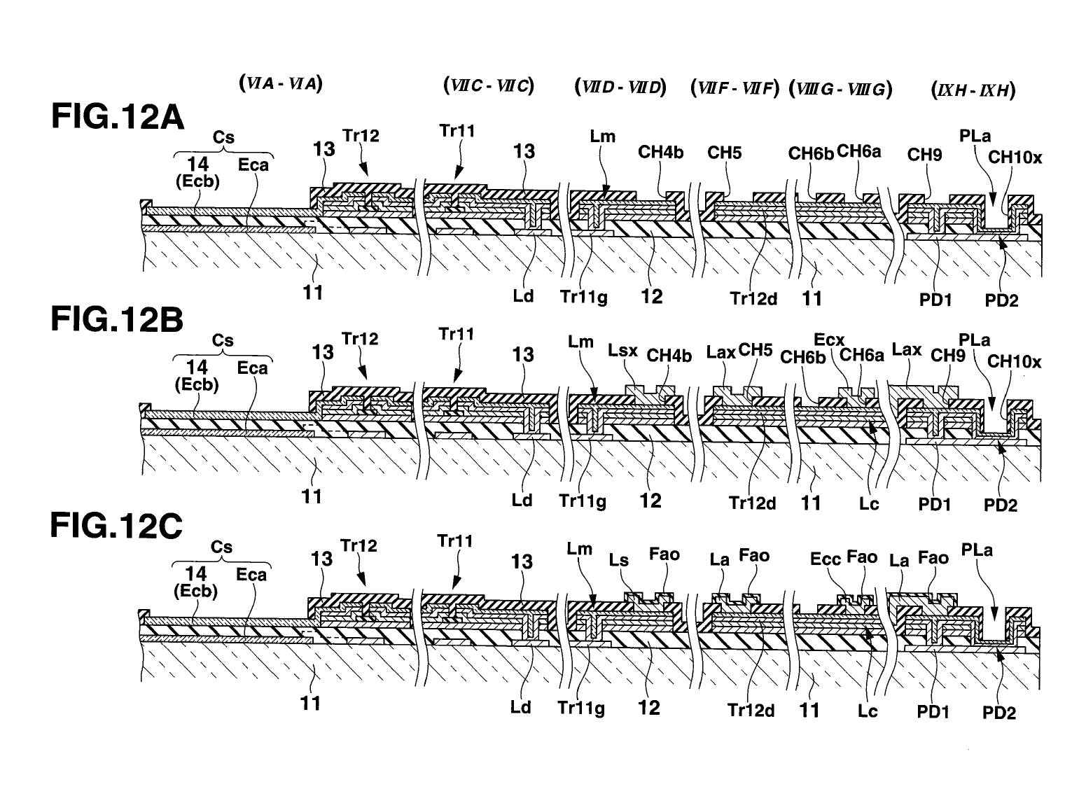

Then, as shown in FIG. 12A, an insulating film 13 which is made of an inorganic insulating material such as silicon nitride and which functions as an interlayer insulating film or protective insulating film is formed by, for example, a chemical vapor deposition (CVD) method all over the substrate 11 including the pixel electrode 14, the transistors Tr11, Tr12, the intermediate layer Lm, the cathode line Lc and the upper pad layer PD2. It is known that the performance of adhesion of ITO and silicon nitride is high. Therefore, in the embodiment, the transparent electrode layer ITO for forming the pixel electrode 14 is also formed on the electrodes and wiring layers comprising the above-mentioned source/drain metal layer SD. Thus, the area of contact between ITO and the insulating film made of silicon nitride is increased, and, for example, the films do not detach easily. Further, the insulating film 13 is patterned by the dry etching method, thereby forming an opening which exposes the upper surface of the pixel electrode 14 of each pixel PIX as well as contact holes CH4b, CH5, CH6a, CH6b, CH9, and an opening CH10x which expose the upper surfaces, at predetermined positions, of the intermediate layer Lm, the drain electrode Tr12d, the cathode line Lc and the upper pad layer PD2.

Then, as shown in FIG. 12B, a wiring layer made of, for example, an aluminum alloy is formed on one side of the substrate 11 by, for example, a sputtering method, and this wiring layer is then patterned by the photolithographic method. Thus, a wiring layer Lsx having a predetermined wiring pattern and serving as the select line Ls, and a wiring layer Lax serving as the power supply voltage line La are formed. At the same time, an electrode layer Ecx serving as the contact electrode Ecc disposed in the peripheral area 30 is also formed. Here, the wet etching is used for the patterning of the wiring layer made of, for example, an aluminum alloy.

In this case, in the display area 20, the wiring layer Lax serving as the power supply voltage line La is electrically connected to the underlayer drain electrode Tr12d through the contact hole CH5 formed in the insulating film 13. In the peripheral area 30, the wiring layer Lax is electrically connected to the upper pad layer PD2 of the terminal pad PLa through the contact hole CH9 formed in the insulating film 13. Moreover, in the display area 20, the wiring layer Lsx serving as the select line Ls is electrically connected to the underlayer intermediate layer Lm through the contact hole CH4b formed in the insulating film 13. In the peripheral area 30, the wiring layer Lsx is electrically connected to the upper pad layer PD2 of the terminal pad PLs through the contact hole formed in the insulating film 13, similarly to the wiring layer Lax. Still further, the electrode layer Ecx serving as the contact electrode is electrically connected to the underlayer cathode line Lc through the contact hole CH6a formed in the insulating film 13.

Then, as shown in FIG. 12C, the wiring layers Lax, Lsx made of, for example, an aluminum alloy and the electrode layer Ecx are anodically oxidized to form an insulating film. Fao comprising an anodic oxide film on the surface layers of the wiring layers Lax, Lsx and electrode layer Ecx. As a result, the inside of the wiring layer which is not anodically oxidized out of the wiring layers Lax, Lsx made of, for example, an aluminum alloy becomes the power supply voltage line La and the select line Ls. The upper surfaces and side surfaces of these lines are covered with the insulating film Fao comprising an anodic oxide film. Further, the inside of the electrode layer Ecx which is not anodically oxidized becomes the contact electrode Ecc. The upper surface and side surface of this electrode are covered with the insulating film Fao comprising an anodic oxide film. Here, among the wiring layers and the electrodes which are made of, for example, an aluminum alloy and which are formed on the substrate 11, those located in the area where the surface layers thereof are not to be formed into insulating films are covered with, for example, a resist in advance to allow no exposure, and then anodically oxidized in this state. When the surface layers of the wiring layers and electrodes are totally formed into insulating films, the step of covering with, for example, the resist can be omitted. More specifically, as shown in the manufacturing method according to the embodiment, the step of covering the wiring layers Lax, Lsx made of, for example, an aluminum alloy and the electrode layer Ecx with, for example, a resist can be omitted in the display panel 10 to which the connection structure of the cathode contact portion shown in FIG. 8B and the terminal structure of the terminal pad shown in FIG. 9B are applied.

Furthermore, the following examples can be advantageously applied as detailed conditions for the anodic oxidation treatment:

(1) Electrolytic Solution for Use in Anodic Oxidation (any One of the Following)

a) ammonium borate solution

b) dilute sulfuric acid

c) oxalic acid

d) electrolyte which is a mixed solution of ethylene glycol and water and which has a volume ratio of about 7:3 to 9:1 and which is, for example, a tartaric acid

e) electrolytic solution adjusted to a pH of about 7.0 by diluting ammonium tartrate with ethylene glycol

f) sulfuric acid solution

g) ammonium tartrate

In the embodiment, 2.5% of a) ammonium borate solution is used.

(2) Electrode Material (Negative Electrode)

a) platinum (Pt)

(3) Electrode Shape

a) meshed

b) flat plate

(4) Treatment Voltage/Treatment Time

current density: 4.5 mA/cm² (within 3 to 15 mA/cm²), formation current: 3.4 A, formation voltage: 200 V, final formation current: 0.06 A (a maturation time of 60 sec is provided after a value of 0.06 A is reached).

When the anodic oxidation treatment is carried out under the above-mentioned conditions, the wiring layers Lax, Lsx made of, for example, an aluminum alloy having a thickness of about 550 nm or more have to be produced in order to form an anodically oxidized film having sufficient insulating performance on the upper surface of the power supply voltage line La or the select line Ls made of, for example, an aluminum alloy having a thickness of about 400 nm. That is, a thickness of 150 nm of the aluminum alloy 550 nm thick has to be formed into an insulating film by the anodic oxidation.

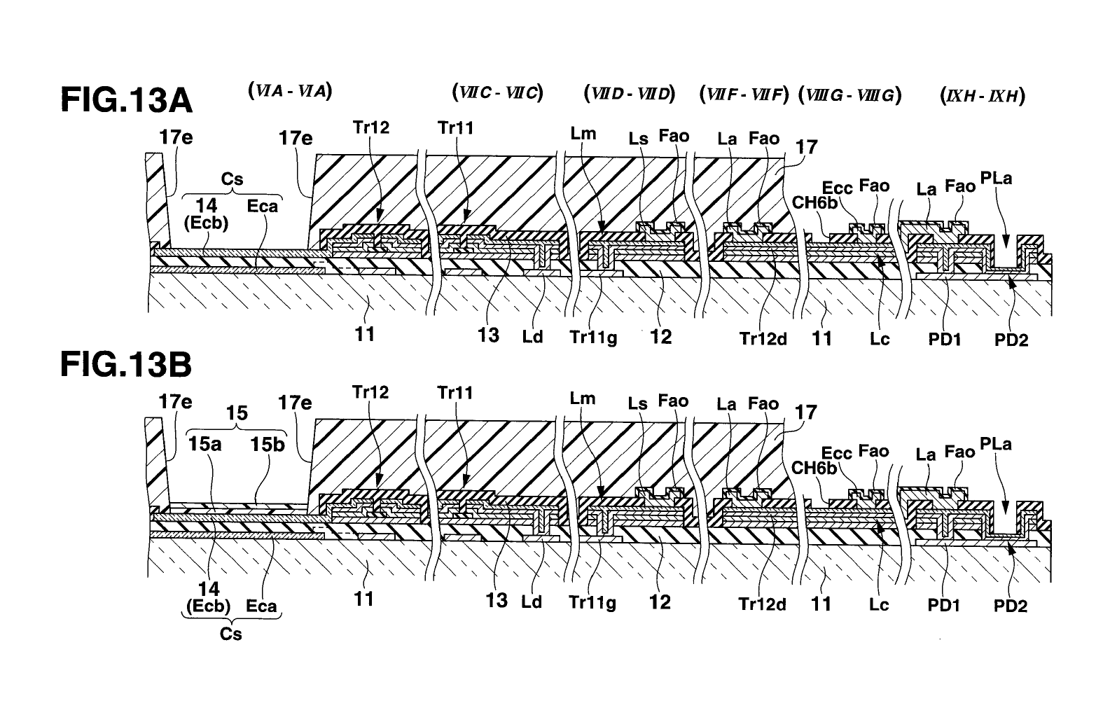

Then, for example, a polyimide or acrylic photosensitive organic resin material is applied onto the substrate 11 to form a resin layer having thickness of about 1 to 5 μm. This resin layer is then patterned to form a partition layer 17 as shown in FIGS. 1A, 1B, and 13A. Here, the partition layer 17 projects to one side of the substrate 11 in at least the display area 20, and has an opening that rectangularly exposes the pixel electrode 14 of each pixel PIX.

As a result, in each pixel formation area Rpx, the opening formed in the partition layer 17, that is, an area surrounded by a sidewall 17e is defined as the EL element formation area Rel of each pixel PIX. Here, for example, a polyimide coating material “Photoneece PW-1030” or “Photoneece DL-1000” manufactured by Toray Industries, Inc. can be advantageously applied as the photosensitive organic resin material for forming the partition layer 17.

Then, after the substrate 11 is cleaned with pure water, the surface of the pixel electrode 14 that is exposed in each EL element formation area Rel defined by the partition layer 17 is made lyophilic to an organic-compound-containing solution such as a later-described hole transport material or electron transport light-emitting material by, for example, an oxygen plasma treatment or UV ozone treatment.

Thus, an area where the organic-compound-containing solution is applied is defined by the partition layer 17, and the surface of the pixel electrode 14 of each pixel PIX (organic EL element OEL) is made lyophilic. Consequently, even when the organic-compound-containing solution is applied by a nozzle printing method or inkjet method to form a light-emitting layer (electron transport light-emitting layer 15b) of the organic EL layer 15 as described later, the organic-compound-containing solution can be suppressed from leaking or climbing over to the EL element formation areas Rel of the pixels PIX of different colors which are arranged adjacently in the column direction of the display panel 10. Therefore, even in manufacturing the display panel 10 adapted to color display, mixing of the colors of adjacent pixels is prevented, so that light-emitting materials of red (R), green (G), and blue (B) can be separately applied in a satisfactory manner.

Although the step of making the surface of the pixel electrode 14 lyophilic has been only described in the embodiment, the present invention is not limited to this. After the above-mentioned treatment for making the surface of the pixel electrode 14 lyophilic, at least the surface of the partition layer 17 may be made lyophobic. As a result, the surface of the partition layer 17 has a lyophobic property, and a substrate surface in which the surface of the pixel electrode 14 exposed in each EL element formation area Rel is lyophilic can be obtained. This enables further suppression of phenomenon in which the organic-compound-containing solution applied to the surface of the substrate 11 rises up on the sidewall 17e of the partition layer 17. Moreover, the organic-compound-containing solution well adapts to the surface of the pixel electrode 14 and expands thereon in a substantially uniform state. In consequence, the organic EL layer 15 (the hole transport layer 15a and the electron transport light-emitting layer 15b) having a substantially uniform thickness can be formed all over the pixel electrode 14.

Furthermore, the term “lyophobic” used in the embodiment is defined as a condition where a contact angle of about 50° or more is measured when the following liquid is dropped on, for example, an insulating substrate: an organic-compound-containing solution including the hole transport material to be the later-described hole transport layer, an organic-compound-containing solution including the electron transport light-emitting material to be the electron transport light-emitting layer, or an organic solvent used for the above solutions. Moreover, the term “lyophilic” as opposed to the term “lyophobic” is defined in the embodiment as a condition where the contact angle is about 40° or less, preferable about 10° or less.

Then, as shown in FIG. 13B, the organic EL layer (light-emitting function layer) 15 in which the hole injection layer (carrier transport layer) 15a and the electron transport light-emitting layer (carrier transport layer) 15b are stacked and formed is formed on the pixel electrode 14 exposed in the EL element formation area Rel of each pixel PIX in the display area 20.

First, a solution or dispersion liquid of the hole transport material is applied to the EL element formation area Rel of each pixel PIX by, for example, the nozzle printing (or nozzle coat) method which injects a continuous solution (liquid flow) or the inkjet method which injects separate discontinuous liquid drops at predetermined positions. The solution or dispersion liquid is heated and dries so that the hole transport layer 15a is formed on the pixel electrode 14.

More specifically, for example, a polyethylenedioxythiophene/polystyrene sulfonate solution (PEDOT/PSS; a dispersion liquid in which polyethylenedioxythiophene PEDOT as a conducting polymer and polystyrene sulfonate PSS as a dopant are dispersed in a water-based solution) is applied to the EL element formation area Rel as an organic-compound-containing solution (organic solution) including an organic-polymer-based hole transport material (carrier transport material). Then, a stage on which the substrate 11 is mounted is heated at a temperature condition of 100° or more for a drying treatment to remove the remaining solvent. As a result, the organic-polymer-based hole transport material is only fixed onto the pixel electrode 14 exposed in each EL element formation area Rel, thereby forming the hole transport layer 15a.

Here, the upper surface of the pixel electrode 14 exposed in each EL element, formation area Rel is lyophilic to the organic-compound-containing solution including the hole transport material owing to the above-mentioned treatment for obtaining the lyophilic property. Therefore, the applied organic-compound-containing solution well adapts to the top of the pixel electrode 14 and expands thereon. On the other hand, the partition layer 17 is formed to be much higher than the height of the surface of the applied organic-compound-containing solution, and the photosensitive organic resin material is generally lyophobic to the organic-compound-containing solution. Therefore, the organic-compound-containing solution can be prevented from leaking or climbing over to the EL element formation area Rel of the adjacent pixel PIX.

Then, a solution or dispersion liquid of the electron transport light-emitting material is applied onto the hole transport layer 15a formed in each EL element formation area Rel by, for example, the nozzle printing method or inkjet method. The solution or dispersion liquid is then heated and dries so that the electron transport light-emitting layer (carrier transport layer) 15b is formed.

More specifically, light-emitting materials of red (R), green (G) and blue (B) including a conjugate double bond polymer based on, for example, polyparaphenylene vinylene or polyfluorene are properly dissolved or dispersed into a water-based solvent or an organic solvent such as tetralin, tetramethylbenzene, mesitylene or xylene. 0.1 wt % to 5 wt % of a solution thus obtained is applied onto the hole transport layer 15a as an organic-compound-containing solution (organic solution) including an organic-polymer-based electron transport light-emitting material (carrier transport material). Then, the stage is heated in a nitrogen atmosphere for a drying treatment to remove the remaining solvent. As a result, the organic-polymer-based electron transport light-emitting material is fixed onto the hole transport layer 15a, thereby forming the electron transport light-emitting layer 15b.

Here, the surface of the hole transport layer 15a formed in the EL element formation area Rel is lyophilic to the organic-compound-containing solution including the electron transport light-emitting material. Therefore, the organic-compound-containing solution applied to each EL element formation area Rel well adapts to the top of the hole transport layer 15a and expands thereon. On the other hand, the partition layer 17 is set to be much higher than the height of the applied organic-compound-containing solution, and the photosensitive organic resin material is generally lyophobic to the organic-compound-containing solution. Therefore, the organic-compound-containing solution can be prevented from leaking or climbing over to the EL element formation area Rel of the adjacent pixel PIE.

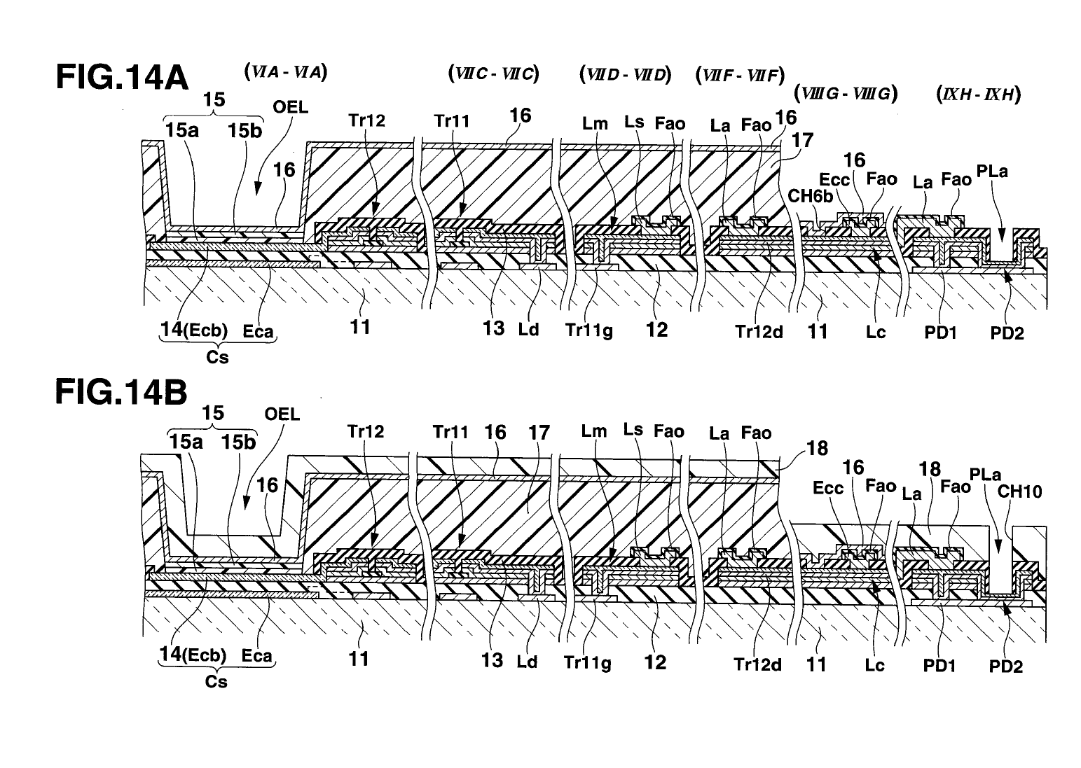

Then, as shown in FIG. 14A, the common opposed electrode (cathode electrode) 16 which has a light reflecting property and which faces the pixel electrode 14 through the organic EL layer 15 of each pixel PIX is formed in at least the display area 20 of the substrate 11 in which the partition layer 17 and the organic EL layer 15 (the hole transport layer 15a and the electron transport light-emitting layer 15b) are formed. At the same time, the opposed electrode 16 is formed to partly extend not only to the display area 20 but also to the peripheral area 30. Thus, the opposed electrode 16 is directly connected to the contact electrode Ecc, and also directly connected to the underlayer cathode line Lc through the contact hole CH6b formed in the insulating film 13.

Here, an electrode structure in which an electron injection layer (cathode electrode) having a low work function and a thin film (power supply electrode) having a high work function are stacked by, for example, a vacuum deposition method or sputtering method can be applied as the opposed electrode 16. The electron injection layer has a thickness of 1 to 10 nm, and is made of, for example, calcium (Ca), barium (Ba), lithium (Li) or indium (In). The thin film has a thickness of 100 nm or more, and is made of a single substance selected from the group consisting of aluminum (Al), chromium (Cr), silver (Ag), and palladium (Pd) or made of an alloy containing at least one of these substances. Here, the wet etching is used for the patterning of the electrode layer that constitutes the opposed electrode 16. In the case of such an electrode structure, the high-work-function thin film of the opposed electrode 16 has only to be connected to the contact electrode Ecc and to the cathode line Lc through the contact hole CH6b.

Then, after the opposed electrode 16 is formed, a sealing layer 18 comprising a silicon oxide film or silicon nitride film is formed by, for example, the CVD method all over one side of the substrate 11, as shown in FIG. 14B. Further, an opening CH10 is formed in the sealing layer 18 to expose the upper surfaces of the terminal pads PLa, PLs (including the unshown terminal pad of the data line Ld) formed in the peripheral area of the substrate 11. Here, the opening CH10 is formed in alignment with, for example, the above-mentioned opening CH10x (see FIG. 12A). As a result, the display panel 10 having a sectional structure shown in FIGS. 6A, 6B, 7A, 70, 7C, 70, 8A, 8B, 9A, and 9B is completed. A metal cap (sealing cap) or sealing substrate such as a glass may be bonded to face the substrate 11 in addition to or instead of the sealing layer 18.

As described above, the display paned (light-emitting panel) and its manufacturing method according to the embodiment are characterized in that at least the uppermost wiring layer (the power supply voltage line La, the select line Ls) among the wiring layers connected to the transistors Tr11, Tr12 formed on the substrate 11 is made of an aluminum alloy material, and the surface layer of this wiring layer is covered with the insulating film Fao comprising an anodic oxide film.

(Examination of Functional Advantages)

Now, functional advantages peculiar to the display panel and its manufacturing method to which the thin film transistor array substrate having the above-mentioned characteristics is applied are described in detail.

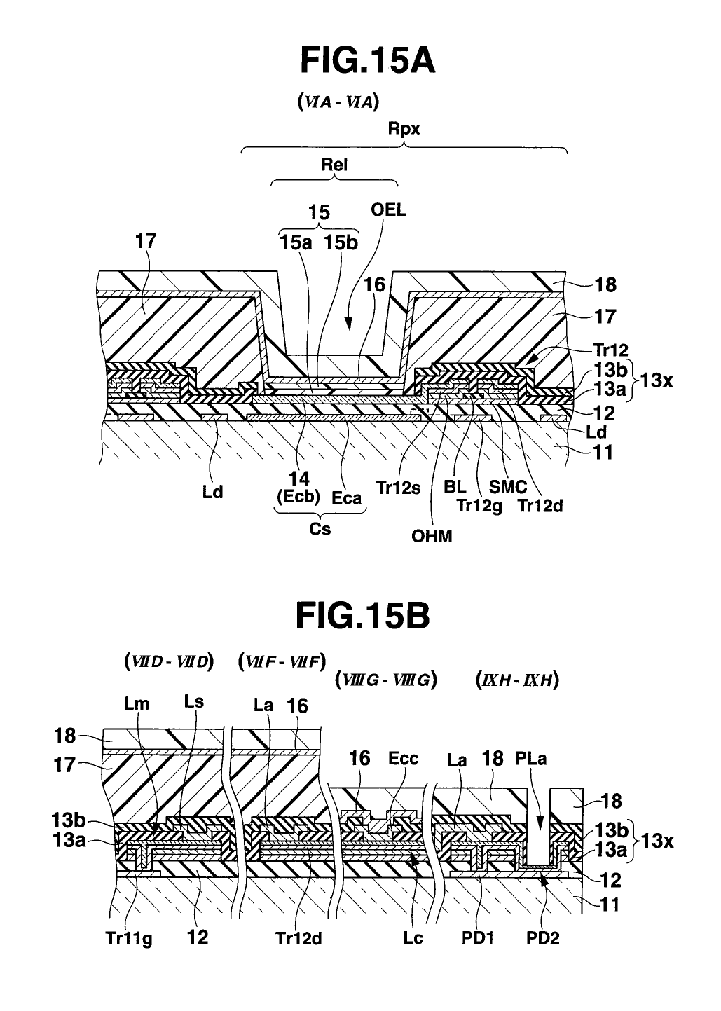

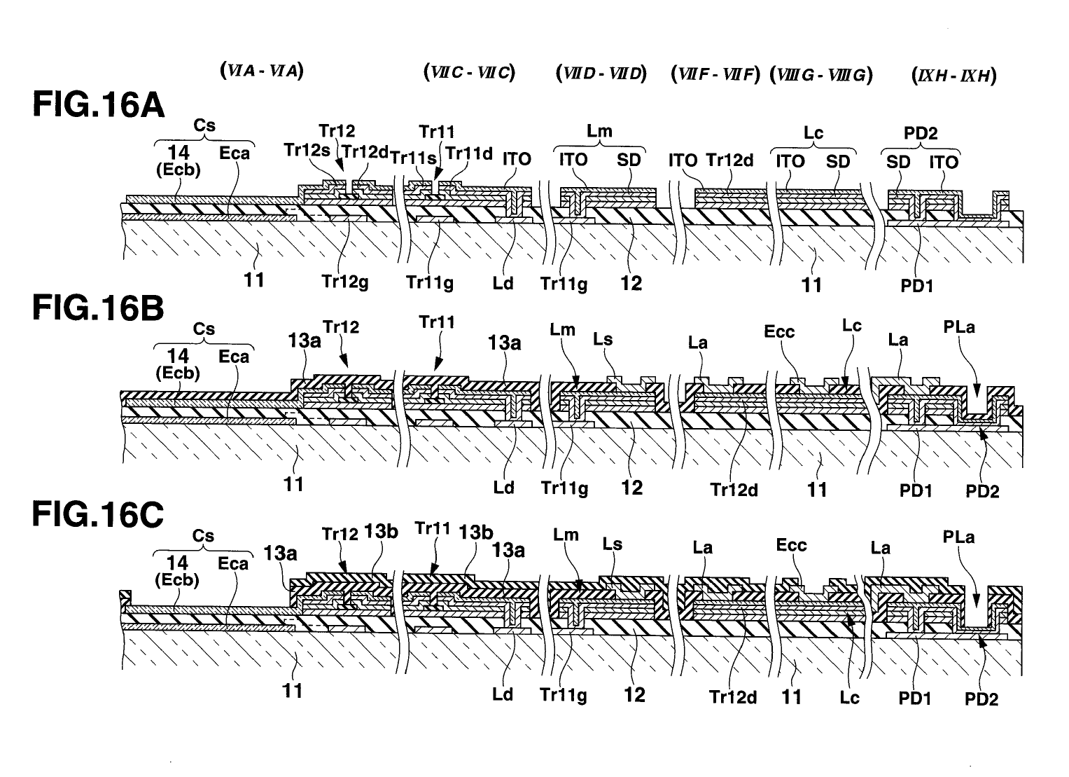

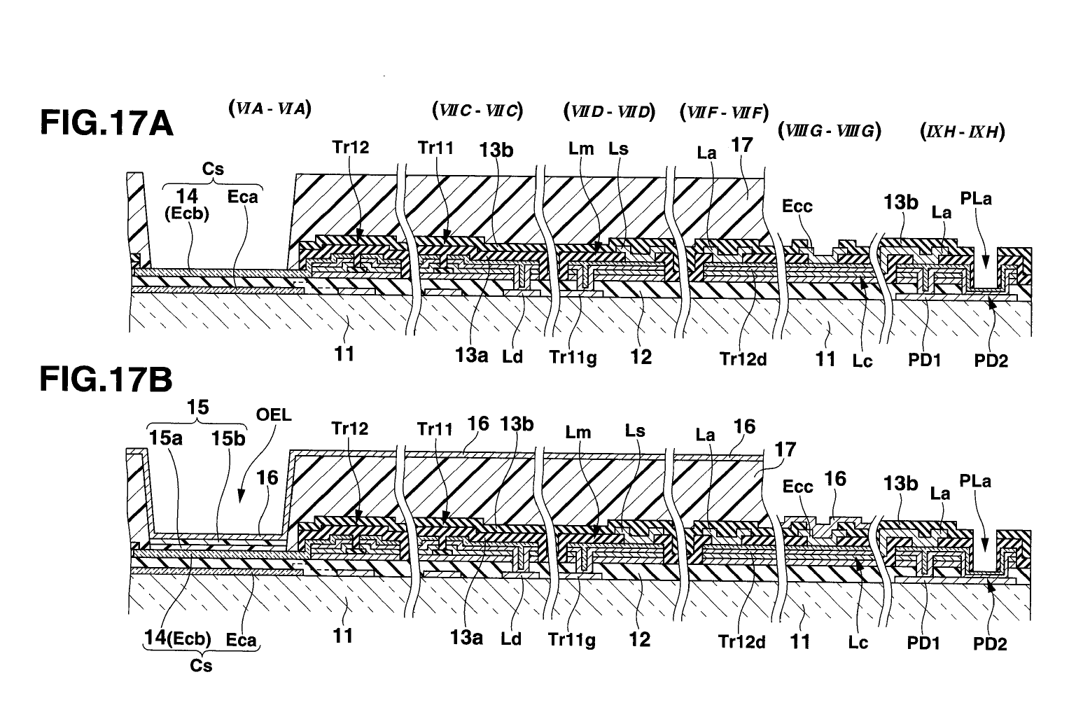

FIGS. 15A and 15B are sectional views of essential parts showing one example of a display panel to be compared with the embodiment described above. Here, to facilitate the comparison with the embodiment described above, marks (VIA-VIA), (VIB-VIB), (VIIC-VIIC), (VIID-VIID), (VIIF-VIIF), (VIIIG-VIIIG), and (IXH-IXH) are used for sections equivalent to the sections in FIGS. 6A, 6B, 7A, 7B, 7C, 7D, 8A, 8B, 9A, and 9B. FIGS. 16A, 16B, 17A, and 17B are process sectional views showing a comparative display panel manufacturing method. Here, to facilitate the comparison with the embodiment described above, sections of parts are adjacently arranged for convenience as in FIGS. 10A, 10B, 10C, 11A, 11B, 11C, 12A, 12B, 12C, 13A, 13B, 14A, and 14B. In the diagrams, (VIA-VIA), (VIB-VIB), (VIIC-VIIC), (VIID-VIID), (VIIF-VIIF), (VIIIG-VIIIG), and (IXH-IXH) show process sections in the sections shown in FIGS. 15A and 15B. Components equivalent to those in the embodiment described above are provided with the same sings and are simply described.

The comparative display panel is different from the display panel described in the embodiment in the following point: As shown in FIGS. 15A and 15B, an insulating film covering an uppermost wiring layer (power supply voltage line La, select line Ls) among wiring layers connected to transistors Tr11, Tr12 formed on a substrate 11 is made of an inorganic insulating material such as silicon nitride instead of the anodic oxide film.

That is, in a display area of the display panel, the select line Ls electrically connected to a gate electrode Tr11g of the transistor Tr11 and the power supply voltage line La electrically connected to drain electrode of the transistor Tr12 are covered with an insulating film 13b comprising, for example, a silicon nitride film through a contact hole provided in an insulating film 13a. Here, the insulating film 13a provided in a layer under the select line Ls and the power supply voltage line La corresponds to the insulating film 13 in the embodiment described above.

On the other hand, in a peripheral area of the display panel, a contact electrode Ecc electrically connected to a cathode line Lc through the contact hole provided in the insulating film 13a is electrically connected to an opposed electrode 16 of an organic EL element OEL through the contact hole provided in the insulating film 13b covering the contact electrode Ecc. The select line Ls and the power supply voltage line La electrically connected to an upper pad layer PD2 of terminal pads PLs, PLa are covered with the insulating film 13b through the contact hole provided in the insulating film 13a.

In the method of manufacturing the display panel having such a panel structure, as shown in FIG. 16A, the transistors Tr11, Tr12, capacitor Cs, intermediate layer Lm, cathode line Lc, upper pad layer PD2 and lower pad layer PD1 of the terminal pad PLa that constitute the light emission drive circuit DC are first formed on one side of the substrate 11, as in the embodiment described above.

Then, as shown in FIG. 16B, after the insulating film 13a comprising a silicon nitride film is formed all over the substrate 11 by, for example, the CVD method, the contact holes and opening that expose the upper surfaces, at predetermined positions, of the intermediate layer Lm, a drain electrode Tr12d, the cathode line Lc and the upper pad layer PD2 are formed by the dry etching method. Further, a wiring layer made of, for example, an aluminum alloy is formed on the substrate 11 by the sputtering method, and is then patterned by the wet etching method, thereby forming the select line Ls and the power supply voltage line La having predetermined wiring pattern. At the same time, the contact electrode Ecc is formed in a peripheral area 30.

In this case, in the display area 20, the power supply voltage line La is electrically connected to the underlayer drain electrode Tr12d through the contact hole formed in the insulating film 13a. In the peripheral area 30, the power supply voltage line La is electrically connected to the upper pad layer PD2 of the terminal pad PLa through the contact hole formed in the insulating film 13a. Moreover, in a display area 20, the select line Ls is electrically connected to the underlayer intermediate layer Lm through the contact hole formed in the insulating film 13a. In the peripheral area 30, the select, line Ls is electrically connected to the upper pad layer PD2 of the terminal pad PLs through the contact hole formed in the insulating film 13a similarly to the power supply voltage line La (not shown). The contact electrode Ecc is electrically connected to the underlayer cathode line Lc through the contact hole provided in the insulating film 13a.

Then, as shown in FIG. 16C, after the insulating film 13b made of, for example, silicon nitride is formed all over the substrate 11 by the CVD method, the contact holes and opening that expose the upper surfaces, at predetermined positions, of the pixel electrode 14, the contact electrode Ecc and the upper pad layer PD2 are formed by the dry etching method. Here, in the EL element formation area Rel and in the area where the terminal pads PLa, PLs are formed, the insulating films 13b and 13a are sequentially etched in a single etching step so that the contact holes and opening that expose the upper surfaces of the pixel electrode 14 and the upper pad layer PD2 are formed. On the other hand, in the area where the contact electrode Ecc is formed, the insulating film 13b is etched to form the contact hole that exposes the upper surface of the contact electrode Ecc.

Then, as shown in FIG. 17A, in at least the display area on the substrate 11, the partition layer 17 made of a photosensitive organic resin material and having an opening that exposes the pixel electrode 14 of each pixel PIX is formed. As a result, the EL element formation area Rel of each pixel PIX is defined.

Then, after the surface of the pixel electrode 14 exposed in each EL element formation area Rel is made lyophilic, the organic EL layer 15 comprising the hole transport layer 15a and the electron transport light-emitting layer 15h is formed on each pixel electrode 14, as shown in FIG. 17B. Further, the opposed electrode 16 having a light reflecting property is formed in least the display area 20 of the substrate 11. Here, the opposed electrode 16 is formed by a single electrode layer (solid electrode) so that the pixel electrodes 14 face this common opposed electrode through the organic EL layer 15 of pixels PIX. In this case, the opposed electrode 16 is connected to the contact electrode Ecc which is disposed in the peripheral area 30 and which is exposed in the contact hole provided in the insulating film 13b. Thus, the opposed electrode 16 is electrically connected to the cathode line Lc through the contact electrode Ecc.

In the display panel having such a panel structure, after the formation of the light emission drive circuit DC including the transistors Tr11, Tr12, several film formation steps and patterning steps have to be repeated to form the insulating films 13a, 13b and wiring layers such as the select, line Ls and the power supply voltage line La. It is generally known that in the film formation and patterning steps, particles (small foreign objects) are generated during sputtering, resist cleaning and etching and remain on the substrate 11. In particular, particles tend to be generated in the CVD method that is often used for forming the insulating films 13a, 13b and in the dry etching step. Such particles, if present on the substrate, are taken into the film during the film formation. These particles disadvantageously disturb the light generated from the organic EL element OEL (light-emitting element), cause a pixel failure such as a point defect or luminance decrease, and decrease manufacturing yield. The problem of such particles is that their effect is relatively high particularly when the display panel is enhanced in the image quality or increased in the size of its screen.

On the contrary, in the panel structure of the display panel 10 according to the embodiment described above, the surface layer of a wiring layer such as the select line Ls or the power supply voltage line La is covered with the insulating film Fao comprising an anodic oxide film. Thus, in the manufacturing method according to the embodiment, by conducting the anodic oxidation treatment after the formation of a wiring layer such as the select line Ls or the power supply voltage line La, the surface layer of this wiring layer can be formed into an insulating film. This allows the step of forming and patterning the insulating film 13b shown in the comparison to be omitted. That is, the CVD process used for the formation of the insulating film 13b and the dry etching step used for pattering can be reduced in number in the manufacturing method according to the embodiment. This suppresses the generation of particles to reduce the defective rate of the display panel (thin film transistor array substrate), improving manufacturing yield.

Furthermore, if simple aluminum or an alloy material containing aluminum is applied as a wiring layer such as the select line Ls or the power supply voltage line La, an anodic oxide film (insulating film Fao) having a good insulating property can be formed on the surface layer. In addition, if simple aluminum or an alloy material containing aluminum is applied as a wiring layer, wiring resistance can be sufficiently reduced. Therefore, even when the display panel 10 is increased in definition or increased in the size of its screen, a signal delay or voltage drop is suppressed, so that the pixel PIX can emit light with a luminance gradation corresponding to image data, and deterioration in image quality can be suppressed.

In the embodiment described above, the circuit configuration adapted to a voltage-specifying type gradation control method has been shown as the light emission drive circuit DC provided in the pixel PIX (see FIG. 3). In this circuit configuration, the value of the gradation voltage Vdata for writing into each pixel PIX (more specifically, the gate terminal of the transistor Tr12 of the light emission drive circuit DC; the contact N11) is adjusted (specified) in accordance with the image data. Thus, the value of the light emission drive current passed through the organic EL element OEL is controlled to enable light emission with a desired luminance gradation. The present invention is not limited to this. The present invention may also be applied to a circuit, configuration adapted to a current-specifying type gradation control method in this case, the value of a gradient current for writing into each pixel PIX is adjusted (specified) in accordance with the image data. Thus, the value of the light emission drive current passed through the organic EL element OEL is controlled to enable light, emission with a desired luminance gradation. One example of this is shown below.

(Another Pixel Example)

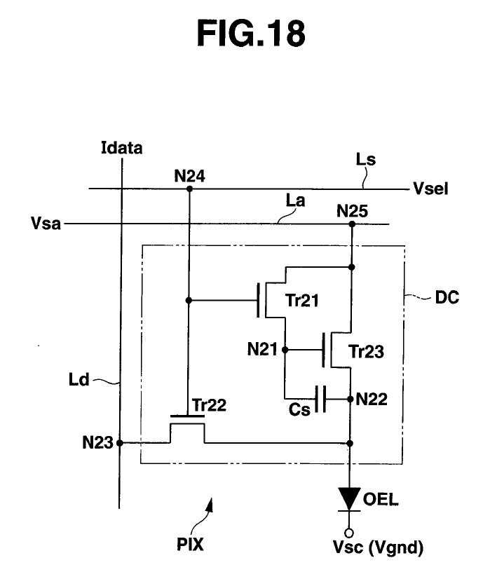

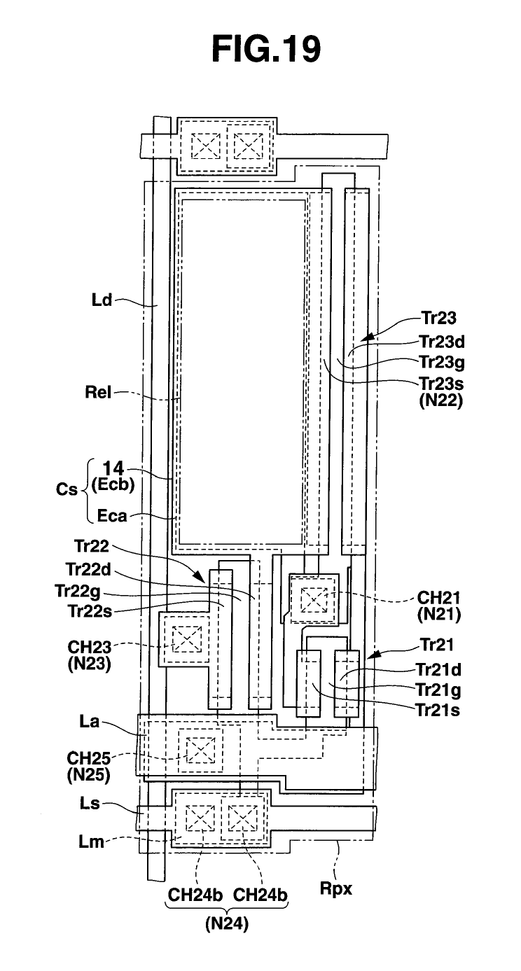

FIG. 18 is an equivalent circuit diagram showing another example of the circuit configuration of the pixels arranged in the display panel according to the embodiment. FIG. 19 is a plan layout view showing the other example of a pixel applicable to the embodiment. Here, components identical or equivalent to those in the pixel (see FIG. 3) shown in the embodiment described above are provided with the same sings and are simply described.

A pixel PIX of the other circuit configuration includes a light emission drive circuit DC having three transistors, and an organic EL element OEL, as shown in FIG. 18. More specifically, the light emission drive circuit DC includes transistors Tr21 to Tr23 and a capacitor Cs. The transistor Tr21 has its gate terminal connected to the select line Ls through a contact N24, its drain terminal connected to the power supply voltage line La through a contact N25, and its source terminal connected to a contact N21. The transistor Tr22 has its gate terminal connected to the select line Ls through the contact N24, its source terminal connected to the data line Ld through a contact N23, and its drain terminal connected to a contact N22. The transistor (drive transistor) Tr23 has its gate terminal connected to the contact N21, its drain terminal connected to the power supply voltage line La through the contact N25, and its source terminal connected to the contact N22. The capacitor Cs is connected between the gate terminal (contact N21) and source terminal (contact N22) of the transistor Tr23.

Furthermore, as in the pixel (see FIG. 3) shown in the embodiment described above, the organic EL element OEL has its anode (the pixel electrode 14 serving as an anode electrode; see FIG. 19 described later) connected to the contact N22 of the light emission drive circuit DC, and its cathode (opposed electrode serving as a cathode electrode) connected to a predetermined low-potential power supply (reference voltage Vsc; e.g., ground potential Vgnd).

According to the drive control operation in the pixel PIX having such a circuit configuration, the following operations are performed within a predetermined processing cycle: writing operation (select period) for holding a voltage component corresponding to image data, and light emitting operation (unselect period) for causing the organic EL element OEL to emit light with a luminance gradation corresponding to image data after the end of the writing operation.

First, in the operation of writing into the pixel PIX (select period), a select voltage Vsel at a select level (on-level; e.g., high level) is applied to the select line Ls to set the pixel PIX to a selected state. Further, while a power supply voltage Vsa at a low level (voltage level equal to or less than the reference voltage Vsc; e.g., a negative voltage) is being applied to the power supply voltage line La, a gradation current Idata set at a negative current value corresponding to the image data is supplied to the data line Ld.

As a result, the gradation current Idata runs in such a manner as to be drawn out of the pixel PIX in the direction of the data line Ld, and a voltage having a potential lower than that of the low-level power supply voltage Vsa is applied to the source terminal (contact N22) of the transistor Tr23.

Thus, a potential difference is made between the contact N21 and the contact N22 (i.e., between the gate and source of the transistor Tr23), and the transistor Tr23 turns on accordingly. As a result, a write current corresponding to the gradation current Idata runs in the direction of the data line Ld from the power supply voltage line La through the transistor Tr23, the contact N22, the transistor Tr22, and the contact N23.

At the same time, a charge corresponding to the potential difference made between the contact N13 and the contact N14 is accumulated in the capacitor Cs, and held as a voltage component. Further, the power supply voltage Vsa at a level equal to or less than the reference voltage Vsc is applied to the power supply voltage line La, and the write current is set to be drawn out of the pixel PIX in the direction of the data line Ld. Thus, a potential applied to the anode (contact N22) of the organic EL element OEL is lower than the potential (reference voltage Vsc) of the cathode, and therefore, no current runs through the organic EL element OEL and there is no light emission (non-emitting operation).

Then, in the light emitting operation (unselect period) after the end of the writing operation, the select voltage Vsel at an unselect level (low level) is applied to the select line Ls to set the pixel PIX to an unselected state. At the same time, the charge accumulated in the above-mentioned writing operation is held in the capacitor Cs, and the transistor Tr23 therefore maintains an on-state. Further, the power supply voltage Vsa at a high level (voltage level higher than the reference voltage Vsc) is applied to the power supply voltage line La. Thereby, a predetermined light emission drive current runs to the organic EL element OEL from the power supply voltage line La through the transistor Tr23 and the contact N22.

At the same time, since the voltage component held by the capacitor Cs is equivalent to a potential difference for passing a write current corresponding to the gradation current Idata in the transistor Tr23, the light emission drive current running through the organic EL element OEL has a value substantially equal to that of the write current, and the organic EL element OEL emits light with a luminance gradation corresponding to the image data.

(Pixel Device Structure)

The pixel having the circuit configuration shown in FIG. 18 can be obtained by, for example, the device structure (plan layout) shown in FIG. 19. In FIG. 19, a contact hole CH21 that electrically connects a source electrode Tr21s of the transistor Tr21, a gate electrode Tr23g of the transistor Tr23, and the lower electrode Eca of the capacitor Cs corresponds to the contact N21 of the equivalent circuit shown in FIG. 18. A connection point of a source electrode Tr23s of the transistor Tr23 and the pixel electrode 14 serving as the upper electrode bob of the capacitor Cs corresponds to the contact N22. Moreover, a contact hole CH23 that electrically connects a source electrode Tr22s of the transistor Tr22 and the data line Ld corresponds to the contact N23. A contact hole CH24a that electrically connects a gate electrode Tr21g of the transistor Tr21, a gate electrode Tr22g of the transistor Tr22 and the intermediate layer Lm, and a contact hole CH24b that electrically connects the intermediate layer Lm and the select, line Ls correspond to the contact N24. A contact hole CH25 that electrically connects a drain electrode Tr21d of the transistor Tr21, a drain electrode Tr23d of the transistor Tr23, and the power supply voltage line La corresponds to the contact 525.

To the display panel in which the pixels PIX including the contacts N21 to N25 are arranged, the structures in the sectional views of the essential parts shown in FIGS. 6A, 6B, 7A, 7B, 7C, 7D, 8A, 8B, 9A, and 9B in the embodiment described above can be applied substantially as they are. Therefore, as in the embodiment described above, the panel structure in which the surface layer of at least the uppermost wiring layer (the power supply voltage line La, the select line Ls) among the wiring layers connected to the transistors Tr21 to Tr23 formed on the substrate 11 is covered with the insulating film comprising an anodic oxide film can be applied to the display panel (thin film transistor array substrate) comprising the pixel PIX (the light emission drive circuit DC and the organic EL element DEL) according to the other example shown in FIGS. 18 and 19. Thus, the step of forming and patterning the insulating film can be eliminated. This makes it possible to suppress the generation of particles, reduce the defective rate of the display panel (thin film transistor array substrate), and improve manufacturing yield.

The pixel PIX shown in FIGS. 3 and 18 is merely one example of the circuit configuration applicable to the present invention, and the present invention is not limited to this. Moreover, in the device structure (see FIGS. 6A, 6B, 7A, 7B, 7C, 7D, 8A, 8B, 9A, and 9B) of the pixel PIX described above, the electrode/wiring structure has been shown in which the transparent electrode layer ITO configuring the pixel electrode 14 is stacked on the source/drain electrodes formed by the source/drain metal layer SD and the wirings. However, the present invention is not limited to this. The present invention may also be applied to a structure in which the transparent electrode layer ITO is only electrically connected to the source electrode of the transistor Tr12 or Tr23 which is a drive transistor of the light emission drive circuit DC and is not formed on other electrodes and wirings.

Furthermore, although the bottom emission type light emission structure is provided as the element structure of the organic EL element DEL in the embodiment described above, the present invention is not limited to this. The present invention may be applied to a top emission type light emission structure. Although the organic EL layer 15 comprises the hole transport layer 15a and the electron transport light-emitting layer 15b in the embodiment described above, the present invention is not limited to this. That is, the organic EL element OEL applied to the present invention may have an element structure in which the organic EL layer 15 only comprises, for example, a hole transport and electron transport light-emitting layer, or only comprises a hole transport light-emitting layer and an electron transport layer, or comprises a charge transport layer that properly intervenes between the hole transport light-emitting layer and the electron transport layer, or comprises a combination of other charge transport layers. Moreover, in the embodiment described above, the pixel electrode 14 serves as the anode electrode, and the opposed electrode 16 serves as the cathode electrode. However, the present invention is not limited to this. The pixel electrode 14 may serve as the cathode electrode, and the opposed electrode 16 may serve as the anode electrode. In this case, in the organic EL layer 15, the carrier transport layer in contact with the pixel electrode 14 may be an electron transport layer.

Still further, the organic EL element OEL is applied as the light-emitting element driven by the light emission drive circuit DC to emit light in the embodiment described above, however, the present invention is not limited to this. Any other light-emitting element, for example, a light-emitting diode may be used as long as such an element is a current-controlled light-emitting element.

(Application of Light-Emitting Panel)

Now, an electronic device to which the display panel (display panel comprising the thin film transistor array) according to the above embodiment is applied is described with reference to the drawings. The display panel 10 shown in the embodiment described above is applicable to various electronic devices such as a digital camera, mobile personal computer or mobile telephone.

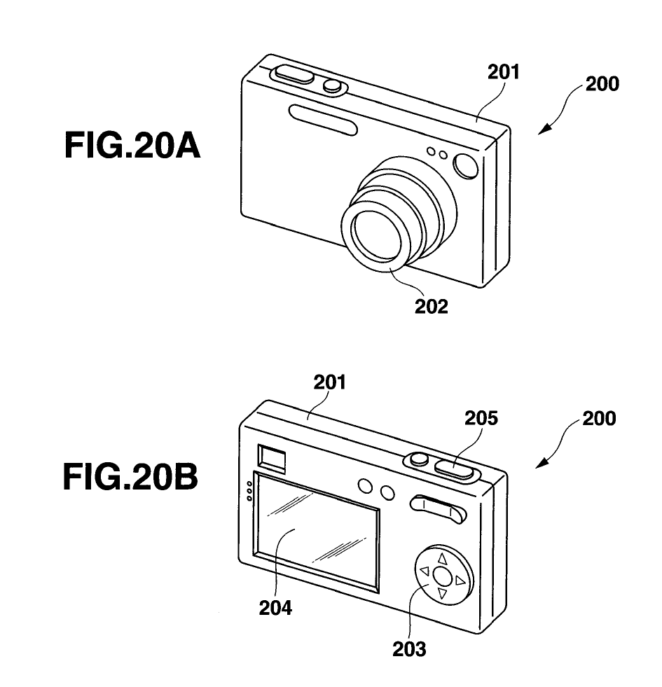

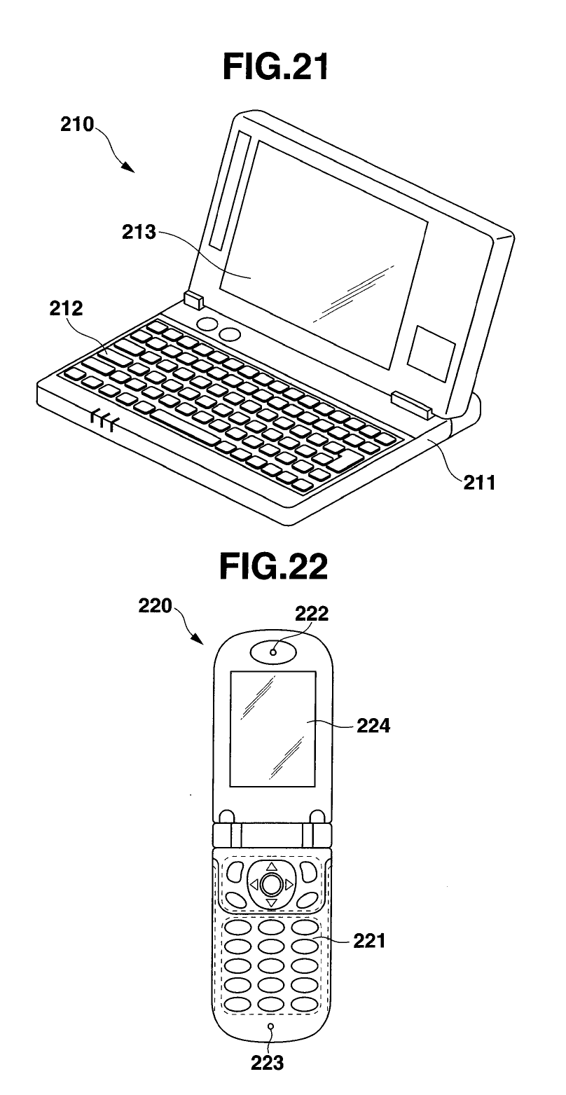

FIGS. 20A and 20B are perspective views showing the configuration of a digital camera according to the application of the embodiment. FIG. 21 is a perspective view showing the configuration of a mobile personal computer according to the application of the embodiment. FIG. 22 is a diagram showing the configuration of a mobile telephone according to the application of the embodiment.

In FIGS. 20A and 20B, a digital camera 200 generally includes a main unit 201, a lens unit 202, an operation unit 203, a display unit 204 including the display panel 10 shown in the embodiment described above, and a shutter button 205. This makes it possible to apply, to the display unit 204, the display panel 10 in which occurrence of a pixel failure such as a point defect or luminance decrease is suppressed. Thus, the pixel can emit light with a proper luminance gradation corresponding to image data. Consequently, high and uniform image quality can be obtained.

In FIG. 21, a personal computer 210 generally includes a main unit 211, a keyboard 212, and a display unit 213 including the display panel 10 shown in the embodiment described above. In this case as well, the display panel 10 in which occurrence of a pixel failure such as a point defect or luminance decrease is suppressed can be applied to the display unit 213. Thus, the pixel can emit light with a proper luminance gradation corresponding to image data. Consequently, high and uniform image quality can be obtained.

In FIG. 22, a mobile telephone 220 generally includes an operation unit 221, an earpiece 222, a mouthpiece 223, and a display unit 224 including the display panel 10 shown in the embodiment described above. In this case as well, the display panel 10 in which occurrence of a pixel failure such as a point defect or luminance decrease is suppressed can be applied to the display unit 224. Thus, the pixel can emit light with a proper luminance gradation corresponding to image data. Consequently, high and uniform image quality can be obtained.

Although the thin film transistor array substrate is applied to the organic EL display panel (light-emitting panel) in the embodiment described above in detail, the present invention is not limited to this. The present invention may be applied to, for example, an exposure apparatus. The exposure apparatus includes a light-emitting element array in which pixels PIX having organic EL elements OEL are arranged on one side. Light emitted from this light-emitting element array in accordance with image data is applied to a photoconductor drum to carry out exposure. Moreover, the present invention is not limited to the light-emitting panel. The present invention is also applicable to, for example, a liquid crystal display apparatus or two-dimensional sensor as long as such a device uses a thin film transistor array substrate in which drive control thin film transistors are arranged on a substrate.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A thin film transistor array substrate comprising:
a substrate;
thin film transistors formed on the substrate; and
wirings which ace provided on the substrate and to which a voltage to drive circuits including the thin film transistors is applied, at least part of the surface of each of the wirings comprising an anodic oxide film.

2. The thin film transistor array substrate according to claim 1, wherein the wirings are made of aluminum or an alloy material containing aluminum.

3. The thin film transistor array substrate according to claim 1, wherein the wirings are patterned by a wet etching method.

4. The thin film transistor array substrate according to claim 1, wherein the wirings comprise power supply voltage lines to which a power supply voltage to drive the circuits is applied.

5. The thin film transistor array substrate according to claim 4, wherein
the circuits comprise pixels regularly arranged on the substrate, and
the thin film transistors comprise drive transistors to drive the pixels in accordance with the power supply voltage applied through the power supply voltage lines.

6. The thin film transistor array substrate according to claim 1, wherein the anodic oxide film has a thickness of 150 nm or more.

7. A light-emitting panel comprising:
a substrate;
light-emitting elements formed on the substrate;
thin film transistors configured to drive the light-emitting elements; and
wirings to which a voltage to drive the light-emitting elements is applied by the thin film transistors, at least part of the surface of each of the wirings comprising an anodic oxide film.

8. The light-emitting panel according to claim 7, wherein
each of the light-emitting elements comprises a first electrode formed on the substrate, a second electrode formed on the first electrode, and a light-emitting layer formed between the first electrode and the second electrode, and
each of the wirings is formed on a layer which is made of the same material as the first electrode and which is provided on the same surface as the first electrode.

9. The light-emitting panel according to claim 8, wherein the first electrode and the layer which is provided on the same surface as the first electrode are made of a transparent conducting material.

10. The light-emitting panel according to claim 7, wherein the wirings are made of aluminum or an alloy material containing aluminum.

11. The light-emitting panel according to claim 7, wherein the wirings are patterned by a wet etching method.

12. The light-emitting panel according to claim 7, wherein the wirings are power supply voltage lines to which a power supply voltage to drive circuits including the thin film transistors is applied.

13. The light-emitting panel according to claim 12, wherein
the circuits are pixels regularly arranged on the substrate, and
the thin film transistors are drive transistors to drive the pixels in accordance with the power supply voltage applied through the power supply voltage lines.

14. An electronic device comprising the light-emitting panel according to claim 7 mounted thereon.

15. A method of manufacturing a light-emitting panel, which includes a substrate provided with pixels including at least light-emitting elements and thin film transistors to drive the light-emitting elements, comprising:
forming wirings to which a voltage to drive the light-emitting elements is applied; and
forming at least cart of the surface of each of the wirings by an anodic oxidation treatment.

16. The light-emitting panel manufacturing method according to claim 15, wherein the wirings are made of aluminum or an alloy material containing aluminum.

17. The light-emitting panel manufacturing method according to claim 15, wherein the wirings are patterned by a wet etching method.

18. The light-emitting panel manufacturing method according to claim 15, wherein the wirings comprise power supply voltage lines to which a power supply voltage to drive circuits including the thin film transistors is applied.

19. The light-emitting panel manufacturing method according to claim 15, wherein the anodic oxidation treatment uses platinum as a negative electrode material.

20. The light-emitting panel manufacturing method according to claim 15, wherein an electrolytic solution used in the anodic oxidation treatment comprises a material selected from the group consisting of an ammonium borate solution, a dilute sulfuric acid, an oxalic acid, an ethylene glycol mixture, an ammonium tartrate mixture, a sulfuric acid solution, and ammonium tartrate.
